(19) United States
(12) Patent Application Publication
(10) Pub. No.: US 2024/0321821 A1
(43) Pub. Date: Sep. 26, 2024

(54) PACKAGING METHOD AND PACKAGING STRUCTURE OF MULTI-LAYER STACKED MEMORY

(71) Applicant: TONGFU MICROELECTRONICS CO., LTD., Nantong (CN)

(72) Inventor: Maohua DU, Nantong (CN)

(21) Appl. No.: 18/731,884

(22) Filed: Jun. 3, 2024

Related U.S. Application Data
(63) Continuation of application No. PCT/CN2022/137241, filed on Dec. 7, 2022.

(30) Foreign Application Priority Data
Dec. 8, 2021 (CN) 202111493772.X
Dec. 8, 2021 (CN) 202111493774.9
Dec. 8, 2021 (CN) 202111494368.4
Dec. 8, 2021 (CN) 202111494369.9
Dec. 8, 2021 (CN) 202111496798.X

(51) Int. Cl. H01L 23/00; H01L 23/31; H01L 23/48; H01L 25/16; H10B 80/00

(52) U.S. Cl. CPC H01L 24/80; H01L 23/3107; H01L 23/481; H01L 24/08; H01L 25/16; H10B 80/00; H01L 2224/08145; H01L 2224/80895; H01L 2224/80896

(57) ABSTRACT

A packaging method and a packaging structure of a multi-layer stacked memory are provided. The packaging method includes providing a buffer chip, a plurality of dummy chips and a plurality of first memory chips. The dummy chip is provided with a groove body, the buffer chip is provided with a plurality of first conductive vias, and the plurality of first memory chips are provided with a plurality of second conductive vias corresponding to the plurality of first conductive vias. The packaging method also includes respectively fixing each of the plurality of first memory chips in the groove body of the dummy chip to form a plurality of micro-memory modules; and sequentially hybrid-bonding and stacking the plurality of the micro-memory modules on the buffer chip. An orthographic projection of a micro-memory module of the plurality of micro-memory modules on the buffer chip coincides with the buffer chip.

### CROSS-REFERENCE TO RELATED APPLICATIONS

This application is a continuation of International Application No. PCT/CN2022/137241, filed on Dec. 7, 2022, which claims the priority of Chinese Patent Application No. 202111494369.9, filed on Dec. 8, 2021; No. 202111494368.4, filed on Dec. 8, 2021; No. 202111496798.X, filed on Dec. 8, 2021; No. 202111493774.9, filed on Dec. 8, 2021; and No. 202111493772.X, filed on Dec. 8, 2021, the content of all of which is incorporated by reference in their entirety.

### TECHNICAL FIELD

The present disclosure generally relates to the field of semiconductor packaging technologies and, more particularly, relates to a packaging method and a packaging structure of a multi-layer stacked memory and.

### BACKGROUND

For enterprise-level applications such as data centers, a large-capacity high-speed storage becomes a necessity. In response to this demand, high bandwidth memory (HBM) came into being. As shown in FIG. 1, HBM utilizes through-silicon vias (TSVs) 12 to vertically interconnect several memory chips 11, and conducts the data interaction with outside through the underlying buffer chip 10. Due to the high density of TSVs and the advantage of short distance vertical interconnection, the data transmission speed is significantly improved.

At present, the multi-layer chip of HBM adopts the thermal compression bonding (TCB) process. Through a rapid heating, the micro-bumps 14 are connected to the chip back soldering pads 13, and the chip back soldering pads 13 are connected to the through silicon via 12 of the chip. Currently, the composition of the micro-bumps 14 is mainly copper-tin alloy, while the main composition of the chip back soldering pad 13 is nickel-gold alloy. The final stacked structure is protected by the plastic encapsulation layer 15.

In the case of using copper-tin micro-bumps, due to the deformability of tin during reflow, to prevent short circuits between micro-bumps, the spacing between micro-bumps and the height of tin need to be strictly controlled. At present, the spacing is above 40 um. When the spacing is reduced to less than 25 um, due to the too small amount of tin, it will be fully converted into intermetallic compounds under the hot load conditions, resulting in a reliability failure.

Further, memory chips are sensitive to heat. After the multi-layer memory chips are stacked, the heat accumulation will seriously affect the performance of the memory chips. The industry needs a solution with a high heat dissipation for high-bandwidth memory chips.

Further, in the HBM structure, the thickness of the top memory chip 12 may not be too thin because it needs to play a mechanical protection role. However, limited by the aspect ratio the TSV, the case of a certain aperture, the penetration of thick chips may not be achieved. Therefore, at present, the top-most memory chip is a non-perforated structure, because the thermal conductivity of silicon is not as good as that of metal, the heat dissipation is limited.

In view of the above problems, there is a need to develop a packaging method and a packaging structure of the multi-layer stacked memory with a reasonable design and can effectively solve the above problems and other problems in the art.

### SUMMARY

One aspect of the present disclosure provides a packaging method of a multi-layer stacked memory. The packaging method includes providing a buffer chip, a plurality of dummy chips and a plurality of first memory chips, wherein a dummy chip of the plurality of dummy chips is provided with a groove body, the buffer chip is provided with a plurality of first conductive vias, and the plurality of first memory chips are provided with a plurality of second conductive vias corresponding to the plurality of first conductive vias; respectively fixing each of the plurality of first memory chips in the groove body of the dummy chip to form a plurality of micro-memory modules; and sequentially hybrid-bonding and stacking the plurality of the micro-memory modules on the buffer chip, wherein an orthographic projection of a micro-memory module of the plurality of micro-memory modules on the buffer chip coincides with the buffer chip.

Another aspect of the present disclosure provides a packaging method of a multi-layer stacked memory. The packaging method includes providing a buffer chip, a dummy chip and a plurality of first memory chips, wherein the dummy chip is provided with a groove body, the buffer chip is provided with a plurality of first conductive vias, and the first memory chip is provided with a plurality of second conductive vias corresponding to the plurality of first conductive vias; sequentially performing a hybrid-bonding process on the plurality of first memory chips, and stacking the plurality of first memory chips to form a first stacked memory module; fixing the first stacked memory module in the groove body of the dummy chip to form a micro-memory module; and hybrid-bonding and stacking the micro-memory module on the buffer chip, wherein an orthographic projection of the micro-memory module on the buffer chip coincides with the buffer chip.

Another aspect of the present disclosure provides a packaging method of a multi-layer stacked memory. The packaging method includes providing a buffer chip, a plurality of first dummy chips, second dummy chips, and third dummy chips, and a plurality of first memory chips, wherein each of the plurality of first dummy chips is provided with a first groove body and a plurality of first cooling vias, the buffer chip is provided with a plurality of first conductive vias, and the plurality of first memory chips are provided with a plurality of second conductive vias corresponding to the plurality of first conductive vias; respectively fixing each of the plurality of first memory chips in the first groove body of the corresponding first dummy chip to form a plurality of first micro-memory modules; anodic bonding a second dummy chip and a third dummy sheet, forming a second groove body at a position of the first groove body corresponding the second dummy chip and the third dummy chip, and forming a second cooling via at a position of the third dummy chip corresponding to the first cooling via, wherein the second cooling via is connected to the first cooling via; fixing the first memory chip in the second groove body to form a second micro-memory module; and sequentially hybrid-bonding the second micro-memory module and the plurality of first micro-memory modules on the buffer chip, wherein an orthographic projection of the second micro-memory module and the first memory micro-module on the buffer chip all coincide with the buffer chip.

Another aspect of the present disclosure provides a packaging method of a multi-layer stacked memory. The packaging method includes providing a dummy chip, a buffer chip, a first memory chip and a plurality of second memory chips, wherein the dummy chip is provided with a plurality of first heat dissipation vias, the buffer chip, the first memory chip and the plurality of second memory chips are provided with a plurality of second heat dissipation vias corresponding to the plurality of first heat dissipation vias, and the plurality of second memory chips and the buffer chip are further provided with a plurality of conductive vias; bonding the first memory chip and the dummy chip; sequentially insulating and stacking the plurality of second memory chips on the buffer chip; insulating and stacking the bonded first memory chips on the plurality of second memory chips; forming a plastic encapsulation layer to wrap the dummy chip, the buffer chip, the first memory chip and the plurality of second memory chips.

Another aspect of the present disclosure provides a packaging method of a multi-layer stacked memory. The packaging method includes providing a dummy chip, a substrate, a first memory chip and a plurality of second memory chips, wherein the first memory chip and the plurality of second memory chips are all provided with a plurality of first heat dissipation vias and the plurality of second memory chips are provided with a plurality of conductive vias; sequentially insulating and stacking the plurality of second memory chips on the substrate; insulating and sacking bonding the first memory chip on the plurality of second memory chips; performing a thermal compression bonding on the dummy chip and the first memory chip, wherein a plurality of second heat dissipation vias corresponding to the plurality of first heat dissipation vias are formed on the dummy chip; and forming a plastic encapsulation layer to wrap the dummy chip, the substrate, the first memory chip and the plurality of second memory chips.

Another aspect of the present disclosure provides a packaging structure of a multi-layer stacked memory. The packaging structure includes a buffer chip; and a plurality of micro-memory modules. The buffer chip is provided with a plurality of first conductive vias; the plurality of micro-memory modules are sequentially stacked on the buffer chip, and an orthographic projection of the micro-memory modules on the buffer chip coincides with the buffer chip; each of the micro-memory modules includes a dummy chip and a first memory chip; the dummy chip is provided with a groove body; the groove body is provided with a first memory chip; and the first memory chip is provided with a plurality of second conductive vias corresponding to and electrically connected to the plurality of first conductive vias.

Another aspect of the present disclosure provides a packaging structure of a multi-layer stacked memory. The packaging structure includes a buffer chip; and a plurality of micro-memory modules. The buffer chip is provided with a plurality of first conductive vias; the plurality of micro-memory modules are sequentially stacked on the buffer chip, and an orthographic projection of the plurality of micro-memory modules on the buffer chip coincides with the buffer chip; each of the plurality of micro-memory modules includes a dummy chip and a stacked memory module; the dummy chip is provided with a groove body; the groove body is provided with the stacked memory module; the stacked memory module includes a plurality of first memory chips stacked in sequence; first memory chips in every two adjacent layers are hybrid-bonded; and the first memory chips are provided with a plurality of second conductive vias corresponding to and electrically connected to the plurality of first memory chips.

Another aspect of the present disclosure provides a packaging structure of a multi-layer stacked memory. The packaging structure includes a buffer chip; a plurality of first micro-memory modules; and a second micro-memory module. The buffer chip is provided with a plurality of first conductive vias; the second micro-memory module is hybrid-bonded and stacked on the buffer chip, the plurality of first micro-memory modules are hybrid-bonded and stacked on the second micro-memory module and an orthographic projection of the first micro-memory modules and the second micro-memory module on the buffer chip coincides with the buffer chip; each of the plurality of first micro-memory modules includes a first memory chip and a dummy chip provided with a first groove body and a plurality of first cooling vias; the first groove body is provided with a first memory chip; the first memory chip is provided with a plurality of second conductive vias corresponding to and electrically connected to the plurality of first conducive vias; the second micro-memory module includes a first memory chip, a second dummy chip, and a third dummy chip sandwiched between the first dummy chip and the second dummy chip; the second dummy chip and the third dummy chip are provided with a second groove body corresponding to the first groove body; the second groove body is provided with the first memory chip; and the third dummy chip is provided with a second cooling via corresponding to and connected to the first cooling via.

Another aspect of the present disclosure provides a packaging structure of a multi-layer stacked memory. The packaging structure includes a dummy chip; a buffer chip; a first memory chip; a plastic encapsulation layer; and a plurality of second memory chips. The plurality of second memory chips are stacked on the buffer chip; the first memory chip is disposed on a side of the plurality of second memory chips facing away from the buffer chip; the dummy chip is bonded and connected to a side of the first memory chip facing away from the buffer chip through a bonding structure; the plastic encapsulation layer wraps the dummy chip, the buffer chip, the first memory chip and the plurality of second memory chips; and, the dummy chip is provided with a plurality of first heat dissipation vias, and the buffer chip, the first memory chip and the plurality of second memory chips are all provided with a plurality of second heat dissipation vias corresponding to the plurality of first heat dissipation vias, and the plurality of second memory chips and the buffer chip are further provided with a plurality of conductive vias.

Another aspect of the present disclosure provides a packaging structure of a multi-layer stacked memory. The packaging structure incudes a dummy chip; a substrate; a first memory chip; a plastic encapsulation layer; and a plurality of second memory chips. The plurality of second memory chips are sequentially stacked on the substrate; the first memory chip is disposed on a side of the plurality of second memory chips facing away from the substrate; the dummy chip is disposed on a side of the first memory chip facing away from the substrate and thermal compression bonded with the first memory chip; the plastic encapsulation layer wraps the dummy chip, the substrate, the first memory chip and the plurality of second memory chips; and, the first memory chip and the plurality of second memory chips are all provided with a plurality of first heat dissipation vias, the dummy chip is provided with a plurality of second heat dissipation vias corresponding to the plurality of first heat dissipation vias, and the plurality of second memory chips are provided with a plurality of conductive vias.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates a typical structure of a conventional packaging structure of a multi-layer stacked memory.

FIG. 2 illustrates a flow chart of an exemplary packaging method of a multi-layer stacked memory according to various disclosed embodiments of the present disclosure.

FIGS. 3-10 illustrate structures corresponding to certain steps of the exemplary packaging method in FIG. 2.

FIG. 11 illustrates a flow chart of another exemplary packaging method of a multi-layer stacked memory according to various disclosed embodiments of the present disclosure.

FIGS. 12-20 illustrate structures corresponding to certain steps of the exemplary packaging method in FIG. 11.

FIG. 21 illustrates a flow chart of another exemplary packaging method of a multi-layer stacked memory according to various disclosed embodiments of the present disclosure.

FIGS. 22-36 illustrate structures corresponding to certain steps of the exemplary packaging method in FIG. 21.

FIG. 37 illustrates a flow chart of another exemplary packaging method of a multi-layer stacked memory according to various disclosed embodiments of the present disclosure.

FIGS. 38-45 illustrate structures corresponding to certain steps of the exemplary packaging method in FIG. 37.

FIG. 46 illustrates a flow chart of another exemplary packaging method of a multi-layer stacked memory according to various disclosed embodiments of the present disclosure.

FIGS. 47-53 illustrate structures corresponding to certain steps of the exemplary packaging method in FIG. 46.

### DETAILED DESCRIPTION

The embodiments of the present disclosure will be described below with reference to the accompanying drawings in the embodiments of the present disclosure. Obviously, the described embodiments are only a part of the embodiments of the present disclosure, but not all of the embodiments. Based on the embodiments in the present disclosure, all other embodiments obtained by those of ordinary skill in the art without creative efforts shall fall within the protection scope of the present application.

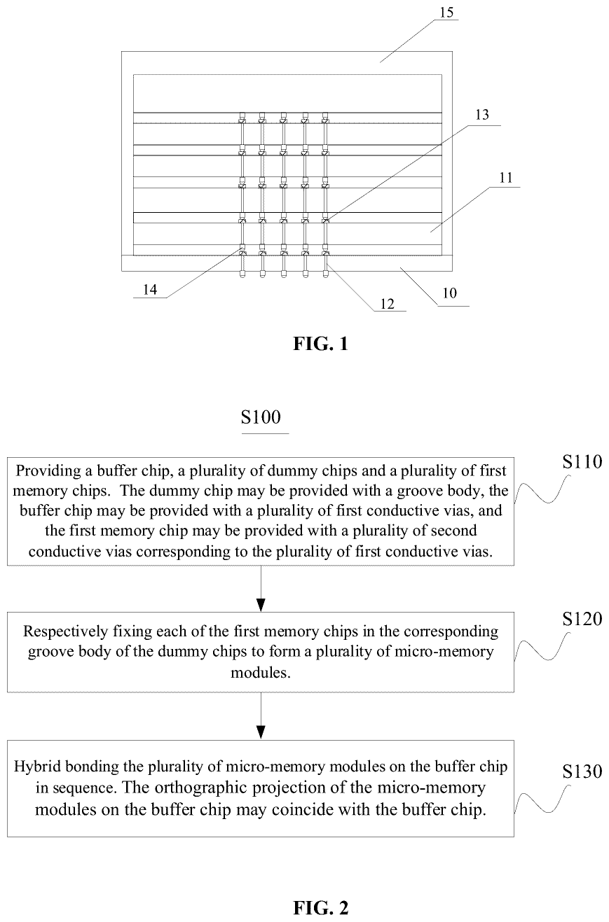

The present disclosure provides a packaging method of a multi-layer stacked memory. FIG. 2 illustrates a flow chart of an exemplary packaging method of a multi-layer stacked memory according to various disclosed embodiments of the present disclosure. As shown in FIG. 2, an exemplary packaging method S100 may include S110: providing a buffer chip, a plurality of dummy chips and a plurality of first memory chips. The dummy chip may be provided with a groove body, the buffer chip may be provided with a plurality of first conductive vias, and the first memory chip may be provided with a plurality of second conductive vias corresponding to the plurality of first conductive vias.

Specifically, as shown in FIG. 10, a buffer chip 110, a plurality of dummy chips 120 and a plurality of first memory chips 130 may be provided. The dummy chip 120 may be provided with a groove body (not shown), the buffer chip 110 may be provided with a plurality of conductive vias 111, and the first memory chip 130 may be provided with a plurality of second conductive vias 131 corresponding to the first conductive vias 111. The first conductive vias 111 and the second conductive through vias 131 may both be through silicon vias (TSVs). The vertical electrical interconnection of TSVs may be realized by using the TSV technology, which may reduce the packaging height.

The packaging method S100 may also include S120: respectively fixing each of the first memory chips in the corresponding groove body of the dummy chips to form a plurality of micro-memory modules.

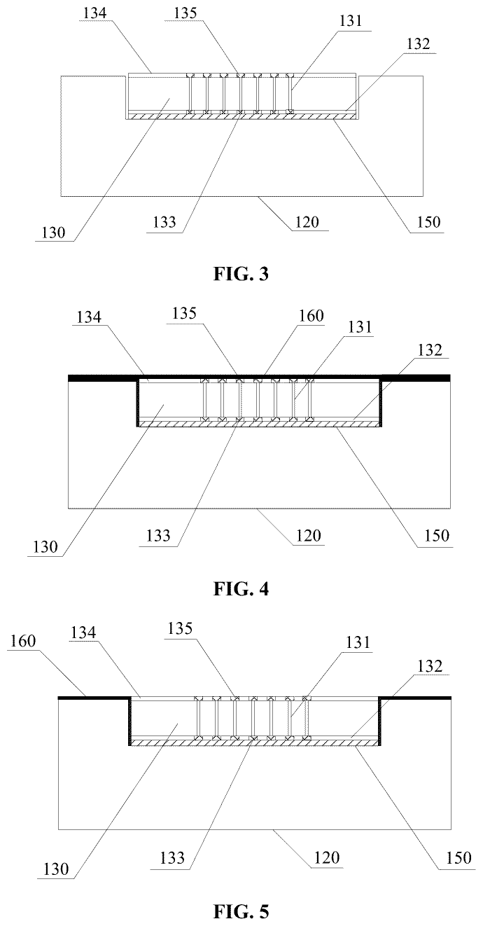

Specifically, as shown in FIG. 3, each first memory chip 130 may be respectively fixed in the groove body of the corresponding dummy chip 120 to form a plurality of micro-memory modules 140. It should be noted that the size of the groove body may be slightly larger than the size of the first memory chip 130, and the depth of the groove body may be lower than the height of the first memory chip 130. For example, the surface of the first memory chip 130 may protrude from the surface of the dummy chip 120.

In one embodiment, as shown in FIG. 3, a first passivation layer 132 and a first metal soldering pad 133 may be disposed on the first surface of the first memory chip 130, and a second passivation layer 134 and a second metal soldering pad 135 may be provided on the second surface of the first memory chip 130. In one embodiment, the first surface of the first memory chip 130 may the back surface, and the second surface of the first memory chip 130 may be the front surface. It should be noted that, in this embodiment, the materials of the first passivation layer 132 and the second passivation layer 134 may both be silicon dioxide or silicon nitride, and the first metal soldering pad 133 and the second metal soldering pads 135 may be both copper pads.

The process for each of the first memory chips to be respectively fixed in the corresponding groove body of the dummy chip to form the plurality of micro-memory modules may further include the following steps.

First, a first adhesive layer may be formed between the bottom wall of the groove body and the first surface of the first memory chip to fix the first memory chip in the groove body.

Specifically, as shown in FIG. 3, a first adhesive layer 150 may be formed between the bottom wall of the groove body and the back surface of the first memory chip 130, and the first adhesive layer 150 may be pressed against the bottom wall of the groove body to fix the first memory chip 130 in the groove body.

Next, a second adhesive layer may be formed on the surface of the dummy chip and the second surface of the first memory chip, and cause a portion of the second adhesive layer to be filled in the gap between the sidewall of the groove body and the first memory chip.

Specifically, as shown in FIG. 4, a second adhesive layer 160 may be formed on the surface of the dummy chip 120 and the front surface of the first memory chip 130, and a portion of the second adhesive layer 160 may be filled in the gap between to the sidewall of the groove body and the first memory chip 130 to further fix the first memory chip 130 in the groove body.

Then, the second adhesive layer on the second surface of the first memory chip may be removed to expose the second passivation layer and the second metal soldering pad.

Specifically, as shown in FIG. 5, a polishing and chemical cleaning process may be performed on the dummy chip 120 and the second surface of the first memory chip 130, and the second adhesive layer 160 on the second surface of the first memory chip 130 may be completely removed to expose the second passivation layer 134 and the second metal soldering pad 135. Meanwhile, the portion of the second adhesive layer 160 on the surface of the dummy chip 120 may be retained. In one embodiment, the second adhesive layer 160 retained on the surface of the dummy sheet 120 may be flush with the second passivation layer 134.

Finally, the first adhesive layer on the first surface of the first memory chip may be removed to expose the first passivation layer and the first metal soldering pad to form the micro-memory module.

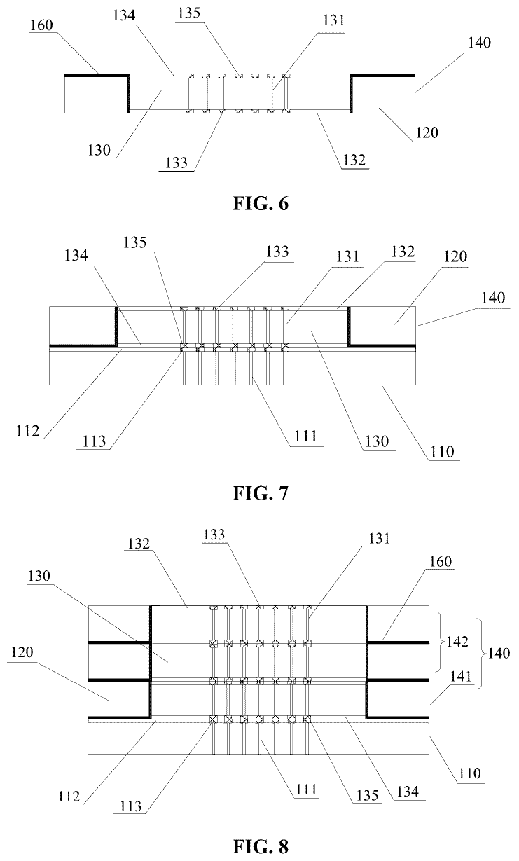

Specifically, as shown in FIG. 6, the side of the dummy chip 120 away from the first memory chip 130, i.e., the backside of the dummy chip 120, may be grinded and polished to remove the silicon on the backside of the dummy chip 120 and the first adhesive layer 150 on the first surface of the first memory chip 130. For example, the backside of the dummy chip 120 may be thinned to completely expose the first passivation layer 132 and the first metal soldering pad 133 to form the micro-memory module 140.

Further, the packaging method S100 may include S130: hybrid-bonding the plurality of micro-memory modules on the buffer chip in sequence. The orthographic projection of the micro-memory modules on the buffer chip may coincide with the buffer chip.

Specifically, as shown in FIG. 7, a side of the buffer chip 110 facing the micro-memory module 140 may be provided with a third passivation layer 112 and a third metal soldering pad 113. In one embodiment, the third passivation layer 112 may be made of silicon dioxide or silicon nitride, and the third metal soldering pad 113 may be a copper pad.

The process for hybrid-bonding the plurality of the micro-memory modules on the buffer chip in sequence may include the following steps.

First, the second passivation layer of the first layer micro-memory module may be bonded to the third passivation layer on the buffer chip, and the second metal soldering pad of the first layer micro-memory module may be bonded to the third metal soldering pad on the buffer chip.

Specifically, as shown in FIG. 7 and FIG. 8, the second passivation layer 134 of the first layer micro-memory module 141 and the third passivation layer 112 on the buffer chip 110 may be hybrid-bonded by a thermal compression bonding process, and the second metal soldering pads 135 of the first layer micro-memory module 140 may be aligned with the third metal soldering pads 113 on the buffer chip 110, and the bonding connection may be realized by the thermal expansion of copper through a high temperature compression. The second adhesive layer 160 remaining on the surface of the dummy chip 120 in the first layer micro-memory module 141 may be attached to the buffer chip 110.

Next, the remaining layers of micro-memory modules may be hybrid-bonded on the first layer micro-memory module in sequence. The first passivation layer in every two adjacent layers of micro-memory modules and the second passivation layer may be bonded; and the first metal soldering pads in every two adjacent layers of micro-memory modules may be bonded with the second metal soldering pads.

Specifically, as shown in FIG. 8, the remaining layers of micro-memory modules 142 may be hybrid-bonded on the first layer micro-memory modules 141 in sequence. The first passivation layer 132 of one of the two adjacent layers of micro-memory modules 140 and the second passivation layer 134 of the other one may be hybrid-bonded under the heating and pressing conditions, and the first metal soldering pad 133 of one of the two adjacent layers of micro-memory modules 140 may be hybrid-bonded with the second metal soldering pad 135 of the other one under heating and pressing.

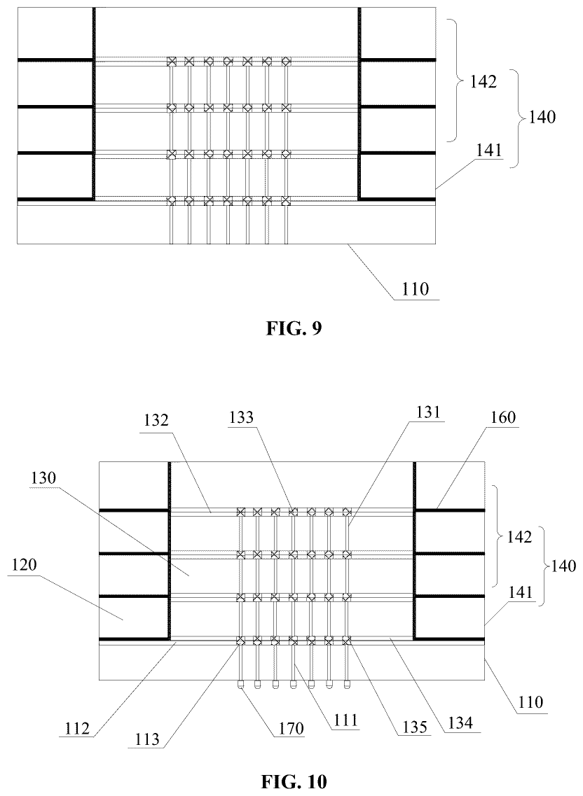

That is to say, as shown in FIG. 9, the first layer micro-memory module 141 may be hybrid-bonded with the buffer chip 110, and the second layer micro-memory module 141 may be disposed on the first layer micro-memory module and may be hybrid-bonded with the first layer micro-memory module 141, and the third layer micro-memory module 141 may be disposed on the second layer micro-memory module and may be hybrid-bonded with the second layer micro-memory module 141, and so on. The micro-memory module 14 in each layer may be sequentially hybrid-bonded and stacked on the buffer chip 110.

As shown in FIG. 10, only the side of the uppermost micro-memory module 140 facing the buffer chip 110 may be provided with the second passivation layer 134 and the second metal soldering pad 135. Because the micro-memory module 140 on the upper most layer may play an important role in the packaging structure, the thickness of the micro-memory module 140 on the top layer may be thicker than that of other micro-memory modules 140, and the first memory chip 130 may not be provided with a second conductive via.

As shown in FIG. 7, FIG. 8, FIG. 9 and FIG. 10, the orthographic projection of the micro-memory module 140 on the buffer chip 110 may coincide with the buffer chip 110. For example, the size of the micro-memory module 140 may be same as that of the buffer chip 110. When the size of the first memory chip 130 is same as that of the buffer chip 110 by adjusting the size of the first memory chip 120 to form the memory micro-module, a wafer-level hybrid-bonding may be realized, and while realizing the high-density interconnection, the bonding efficiency may be greatly improved compared to the single-chip bonding, and the mass production may be enabled.

Further, as shown in FIG. 10, after the plurality of micro-memory modules are sequentially hybrid-bonded on the buffer chip and stacked on the buffer chip, the method may further include forming a plurality of bumps on the surface of the buffer chip facing away from the micro-memory module. The plurality of bumps may correspond to the plurality of first conductive vias.

Specifically, as shown in FIG. 10, a plurality of bumps 170 may be formed on the surface of the buffer chip 110 facing away from the micro-memory module 140, and the plurality of bumps 170 may correspond to the plurality of first conductive vias 111. The bumps 170 may be copper-tin bumps.

After forming the plurality of bumps 170, a dicing process may be performed to form a plurality of independent memory packaging structures.

In the packaging method of a multi-layer stacked memory provided by the present disclosure, each first memory chip may be fixed in the corresponding groove body of the dummy chip to form a plurality of micro-memory modules. The plurality of micro-memory modules may be hybrid-bonded in sequence and stacked on the buffer chip. The orthographic projection of the micro-memory module on the buffer chip may coincide with the buffer chip. The present disclosure may adjust the first memory chip and the buffer chip of two different sizes to the same size through the dummy chip. For example, the size of the micro-memory module and the buffer chip may be adjusted to be same. Thus, the wafer-level hybrid-bonding may be realized. Compared with the single-chip bonding, the efficiency may be greatly improved, achieving mass production and high output rate. In addition, the hybrid-bonding may also be performed between every two adjacent micro-memory modules, which may achieve a smaller spacing. Under the same density, the number of vertical interconnections may be increased, the number of data channels may be increased, and the data throughput may be improved.

The present disclosure also provides a packaging structure of a multi-layer stacked memory. FIG. 10 illustrates an exemplary packaging structure according to various disclosed embodiments of the present disclosure. As shown in FIG. 10, an exemplary packaging structure 100 may include a buffer chip 110 and a plurality of micro-memory modules 140.

The buffer chip 110 may be provided with a plurality of first conductive vias 111. A plurality of micro-memory modules 140 may be stacked on the buffer chip 110 in sequence, and the orthographic projection of the micro-memory module 140 on the buffer chip 110 may coincide with the buffer chip 110.

Each micro-memory module 140 may include a dummy chip 120 and a first memory chip 130. The dummy chip 120 may be provided with a groove body. The groove body may be provided with a first memory chip 130, and the first memory chip 130 may be provided with a plurality of first conductive vias 111 corresponding to and electrically connected to a plurality of second conductive vias 131.

In one embodiment, as shown in FIG. 10, a first passivation layer 132 and a first metal soldering pad 133 may be disposed on the first surface of the first memory chip 130 facing away from the buffer chip 110, and a second passivation layer 134 and a second metal soldering pad 135 may be disposed on the second surface of the first memory chip 130 facing the buffer chip 110.

The first passivation layer 132 and the second passivation layer 134 in every two adjacent layers of the micro-memory modules 140 may be bonded and connected; and the first metal soldering pads 133 and the second metal soldering pads 135 in every two adjacent layers of the micro-memory modules 140 may be bonded and connected.

It should be noted that, in this embodiment, the materials of the first passivation layer 132 and the second passivation layer 134 may be silicon dioxide or silicon nitride, and the first metal soldering pad 133 and the second metal soldering pad 135 may be copper pads.

In one embodiment, as shown in FIG. 10, a surface of the buffer chip 110 facing the micro-memory module 140 may be provided with a third passivation layer 112 and a third metal soldering pad 113.

The third passivation layer 112 may be bonded to the second passivation layer 134 in the first layer micro-memory module 141, and the third metal soldering pad 113 may be bonded and connected to the second metal soldering pad 135 in the first layer micro-memory module 141.

It should be noted that, in this embodiment, the material of the third passivation layer 112 may be silicon dioxide or silicon nitride, and the third metal soldering pad 113 may be a copper pad.

In one embodiment, as shown in FIG. 10, an adhesive layer 160 may be further provided between two adjacent dummy chips 120 and between the sidewall of the groove body and the first memory chip 130. The adhesive layer 160 may further fix the two adjacent micro-memory modules 140.

In one embodiment, as shown in FIG. 10, a plurality of bumps 170 may be provided on the surface of the buffer chip 110 facing away from the micro-memory module 140. The plurality of bumps 170 may correspond to the plurality of first conductive vias 111. In this embodiment, the bumps 170 may be copper-tin bumps.

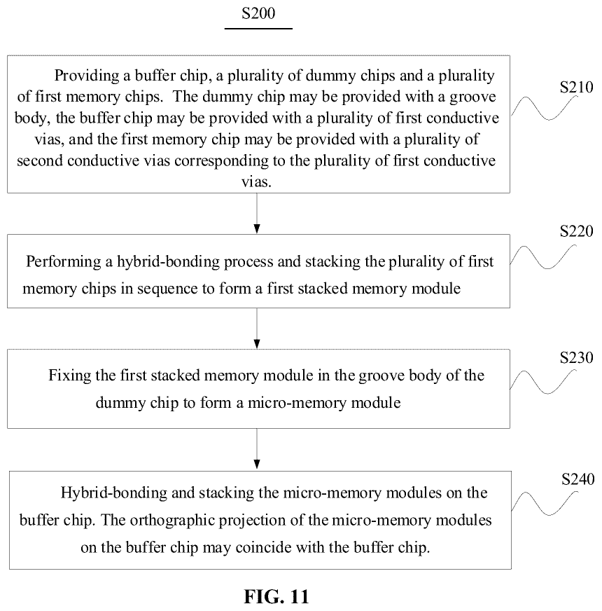

FIG. 11 illustrates a flow chart of another exemplary packaging method of a multi-layer stacked memory according to various disclosed embodiments of the present disclosure. As shown in FIG. 11, an exemplary packaging method S200 may include S210: providing a buffer chip, a plurality of dummy chips and a plurality of first memory chips. The dummy chip may be provided with a groove body, the buffer chip may be provided with a plurality of first conductive vias, and the first memory chip may be provided with a plurality of second conductive vias corresponding to the plurality of first conductive vias.

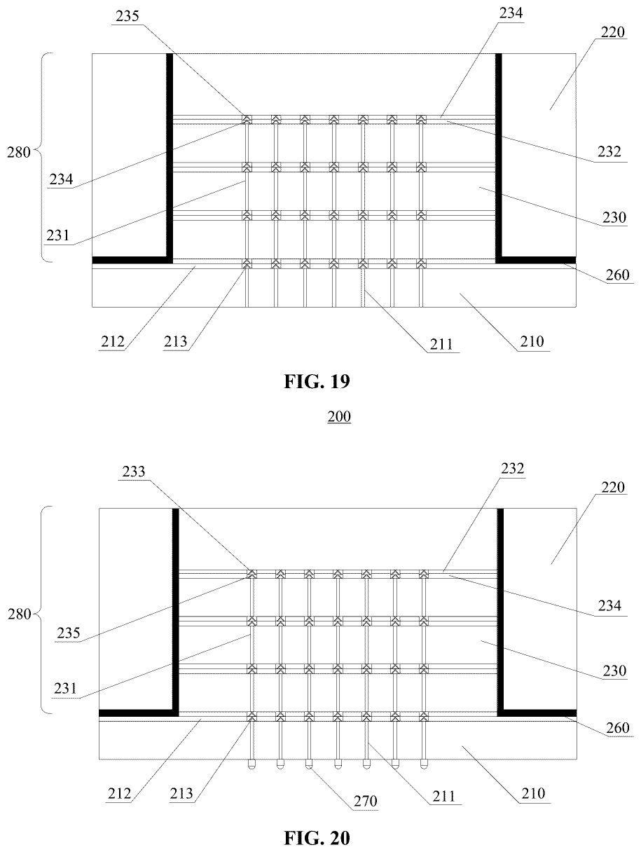

Specifically, as shown in FIG. 20, a buffer chip 210, a plurality of dummy chips 220 and a plurality of first memory chips 230 may be provided. The dummy chip 220 may be provided with a groove body (not shown in the figure), the buffer chip 210 may be provided with a plurality of first conductive vias 211, and the first memory chip 230 may be provided with a plurality of second conductive vias 231 corresponding to the plurality of first conductive vias 211. The first conductive vias 211 and the second conductive through vias 231 may both be through silicon vias (TSVs). The vertical electrical interconnection of TSVs may be realized by using the TSV technology, which may reduce the packaging height. The first memory chip 230 may be a random access memory, or other appropriate memory, which is not limited by the present disclosure.

The packaging method S200 may also include S220: performing a hybrid-bonding process and stacking the plurality of first memory chips in sequence to form a first stacked memory module.

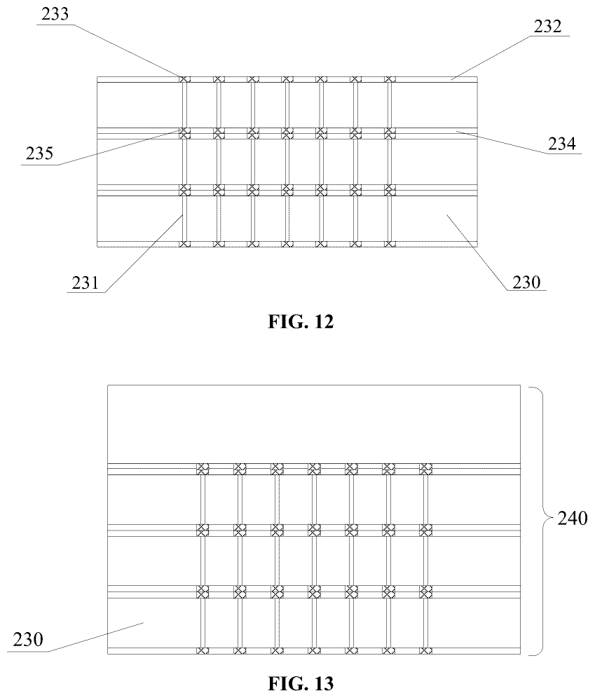

Specifically, as shown in FIG. 12 and FIG. 20, a first passivation layer 232 and a first metal soldering pad 333 may be provided on the first surface of the first memory chip 230 facing away from the buffer chip 210, and a second passivation layer 234 and a second metal soldering pad 235 may be provided on the second surface of the first memory chip 230 facing the buffer chip 210. In this embodiment, the first surface of the first memory chip 230 may be the back side, and the second surface of the first memory chip 230 may be the front side. It should be noted that, in this embodiment, the materials of the first passivation layer 232 and the second passivation layer 234 may both be silicon dioxide or silicon nitride, and the first metal soldering pad 233 and the second metal soldering pad 235 may be copper soldering pads.

The process for hybrid-bonding and stacking the plurality of first memory chips in sequence to form the first stacked memory module may include following steps.

First, the first passivation layer 232 and the second passivation layer 234 in every two adjacent layers of the first memory chips 230 may be bonded. Specifically, as shown in FIG. 12, in every two adjacent layers of the first memory chips 230, the first passivation layer 232 of the lower first memory chip 230 and the second passivation layer 234 of the upper first memory chip 230 may be hybrid-bonded by heating and pressing.

Then, the first metal soldering pads and the second metal soldering pads in every two adjacent layers of first memory chips may be bonded.

Specifically, as shown in FIG. 12, in every two adjacent layers of first memory chips 230, the first metal soldering pad 233 of the lower first memory chip 230 and the second metal soldering pad 235 of the upper first memory chip 230 may be aligned. For example, the first copper soldering pad 233 may be aligned with the second copper soldering pad 235, and then through a high temperature compression, the thermal expansion of copper may be used to realize the bonding connection.

As shown in FIG. 13, through the above steps, the plurality of first memory chips 230 may be hybrid-bonded and stacked in sequence to form a first stacked memory module 240. The number of the first memory chips 230 may be selected according to actual needs, which is not specifically limited in this embodiment. As shown in FIG. 12 and FIG. 13, only on the second surface of the topmost first memory chip 230 in the first stacked memory module 240 facing the buffer chip 210 may be provided with the second passivation layer 234 and the second metal soldering pad 235. Because the first memory chip 230 on the top layer may protect the packaging structure, the thickness of the first memory chip 230 on the top layer may be greater than that of other first memory chips 230, and there may be no conductive vias disposed in the first memory chip 230 on the top layer. The first passivation layer 232 and the first metal pad 233 may not be provided on the first surface of the topmost first memory chip 230 in the first stacked memory module 240 in preparation for the next packaging step.

The packaging method S200 may also include S230: fixing the first stacked memory module in the groove body of the dummy chip to form a micro-memory module. In one embodiment, the step S230 may specifically include the following steps.

First, a first adhesive layer may be formed on the first surface of the top layer first memory chip in the first stacked memory module to fix the first stacked memory module in the groove body.

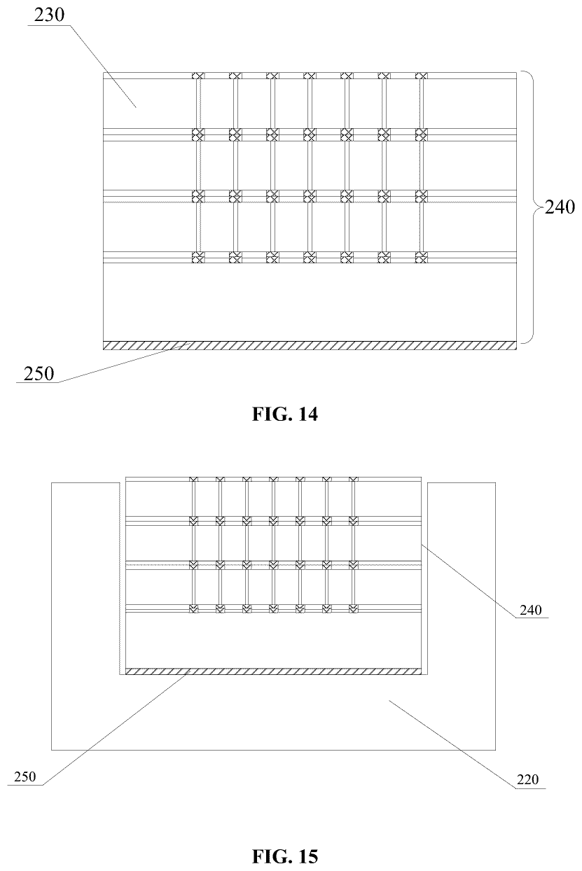

Specifically, as shown in FIG. 14 and FIG. 15, a first adhesive layer 250 may be formed on the first surface of the first memory chip 230 on the top layer of the first stacked memory module 240, and the first adhesive layer 250 may be used to fix the entire first stacked memory module 240 in the groove body in the dummy chip 220.

It should be noted that, in this embodiment, the plurality of first memory chips 230 may be hybrid-bonded, and the plurality of first stacked memory modules 240 may be formed by stacking them in sequence. Therefore, after the first adhesive layer 250 is formed on the first surface of the first memory chip 230 on the top layer first stacked memory module 240, a plurality of first stacked memory modules 240 with the first adhesive layer 250 may need to be divided to form individual first stacked memory modules 240. Then, the independent first stacked memory module 240 with the first adhesive layer 250 may be fixed in the groove body.

It should be further noted that, in this embodiment, as shown in FIG. 15, the size of the groove body may be slightly greater than the size of the first stacked memory module 240, and the depth of the groove body may be smaller than the height of the first stacked memory module 240. For example, the surface of the first stacked memory module 240 may protrude from the surface of the dummy chip 220. The structure above the groove body may be set in preparation for the encapsulation step that follows.

Next, a second adhesive layer may be formed on the second surface of the bottom first memory chip in the first stacked memory module, and a portion of the second adhesive layer may be filled into the gap between the sidewall of the groove body and the first stacked memory module.

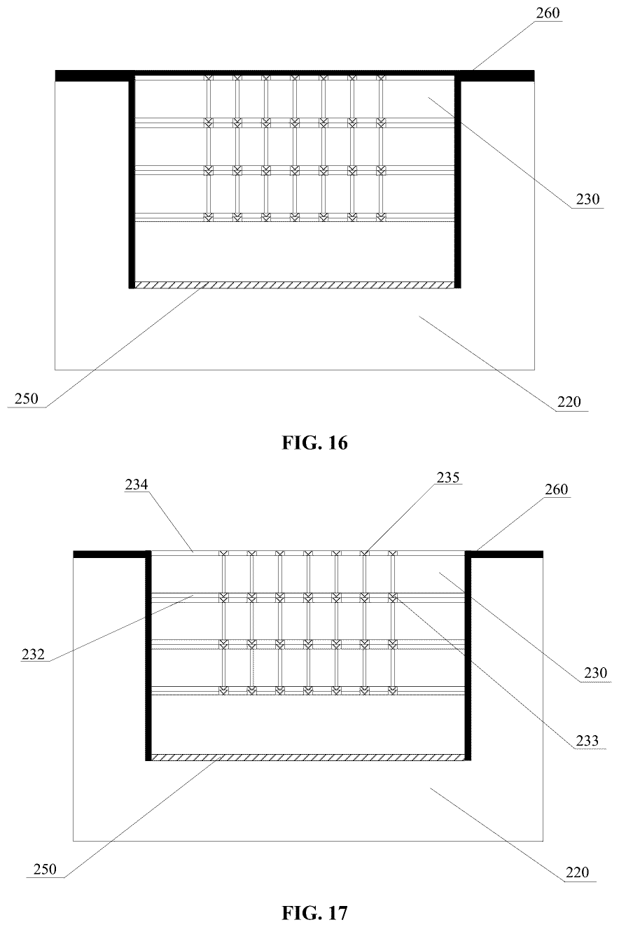

Specifically, as shown in FIG. 16, a second adhesive layer 260 may be formed on the second surface of the bottom layer first memory chip 230 in the dummy chip 220 and the first stacked memory module 240, and the second adhesive layer 260 may be filled into the gap between the sidewall of the groove body and the first stacked memory module 240, and the first stacked memory module 240 may be further fixed in the groove body.

Thirdly, the second adhesive layer on the second surface of the bottom first memory chip may be removed to expose the second passivation layer and the second metal soldering pad.

Specifically, as shown in FIG. 17, a polishing and chemical cleaning process may be performed on the dummy chip 220 and the second surface of the first memory chip 230 to completely remove the second adhesive layer 260 on the second surface of the bottom first memory chip 230 to expose the second passivation layer 234 and the second metal soldering pad 235. Meanwhile, a portion of the second adhesive layer 260 on the surface of the dummy chip 220 may be retained. In this embodiment, the second adhesive layer 260 retained on the surface of the dummy chip 220 may be flush with the second passivation layer 234.

Finally, the first adhesive layer on the first surface of the top layer first memory chip may be removed to form the micro-memory module.

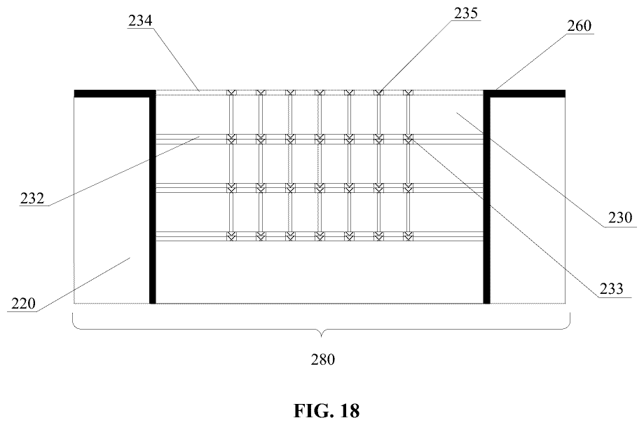

Specifically, as shown in FIG. 18, the first surface of the top layer first memory chip 230 and the dummy chip 220 may be grinded and polished, and the first adhesive layer 250 adhered to the first surface of the top layer first memory chip 230 may be removed. At the same time, a portion of silicon on the dummy wafer 220 may be removed to form a micro-memory module 280 as shown in FIG. 18.

It should be noted that if the thickness of the top layer first memory chip 230 is relatively thick, in this step, the first surface of the top layer first memory chip 230 may need to be grinded and polished to remove a portion of silicon, and then the top layer first memory chip 130 may need to be removed by grinding and polishing to thin the top layer first memory chip 230.

Further, the packaging method S200 may include S240: hybrid-bonding and stacking the micro-memory modules on the buffer chip. The orthographic projection of the micro-memory module on the buffer chip may coincide with the buffer chip.

Specifically, as shown in FIG. 19, a side of the buffer chip 210 facing the micro-memory module 280 may be provided with a third passivation layer 212 and a third metal soldering pad 213. In one embodiment, the third passivation layer 212 may be silicon dioxide or silicon nitride; and the third metal soldering pad 213 may be copper soldering pad.

As shown in FIG. 19, the second passivation layer 234 of the bottom first memory chip 230 in the micro-memory module 280 and the third passivation layer 212 on the buffer chip 210 may be hybrid-bonded by heating and pressing, and the second metal soldering pads 235 of the bottom first memory chip 230 may be aligned with the third metal soldering pads 213 on the buffer chip 210, that is, the second copper soldering pads may be aligned with the third copper soldering pads, and then may be pressed together under a high temperature and pressure, the thermal expansion of copper may be used to realize the bonding connection.

As shown in FIGS. 19-20, the orthographic projection of the micro-memory module 280 on the buffer chip 210 may coincide with the buffer chip 210. For example, the size of the micro-memory module 280 may be same as that of the buffer chip 210. By adjusting the size of the first stacked memory chip module 240 to be same as the size of the buffer chip 210 through the dummy chip 220, that is, the size of the plurality of first memory chips 230 may be adjusted to be the same as the size of the buffer chip 210, to form the micro-memory module 280, the wafer-level hybrid-bonding may be achieved, and the efficiency of hybrid-bonding may be greatly improved compared to the single-chip bonding while achieving high-density interconnection. Accordingly, the mass production may be achieved.

In one embodiment, as shown in FIG. 20, after the hybrid-bonding and stacking of the plurality of the micro-memory modules on the buffer chip, the method may further include following steps.

A plurality of bumps may be formed on the surface of the buffer chip away from the memory module, and the plurality of bumps may correspond to the plurality of first conductive vias.

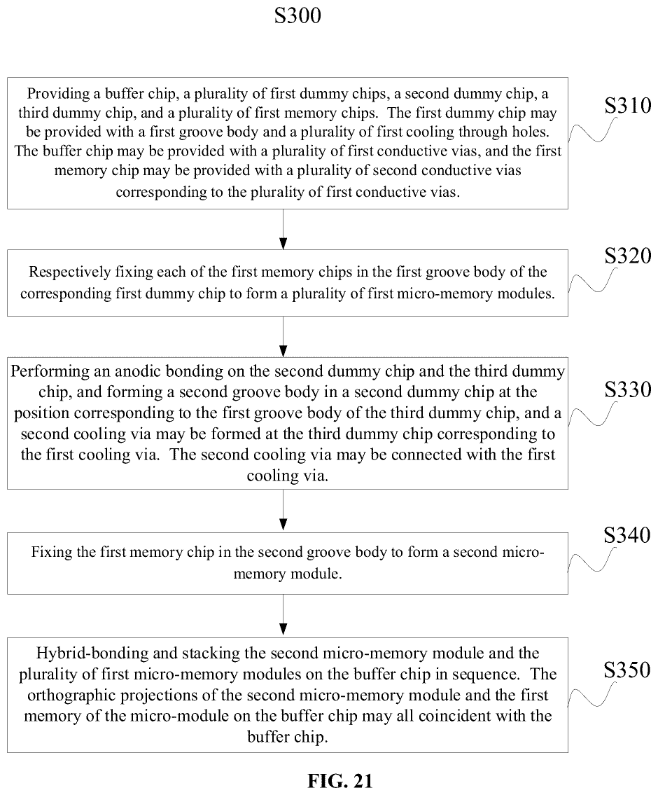

Specifically, as shown in FIG. 21, a plurality of bumps 270 may be formed on the surface of the buffer chip 210 away from the micro-memory module 280, and the plurality of bumps 270 may correspond to the plurality of first conductive vias 211. The bumps 270 may be copper-tin bumps. After forming the plurality of bumps 270, a dicing process may be performed to form a plurality of independent memory packaging structures.

In the packaging method of the multi-layer stacked memory provided by the present disclosure, a plurality of the first memory chips may be hybrid-bonded, and stacked in sequence to form a first stacked memory module, and the first stacked memory module may be fixed in the groove body of the dummy chip to form a micro-memory module, and the micro-memory module may be hybrid-bonded and stacked on the buffer chip. The orthographic projection of the micro-memory module on the buffer chip may coincide with the buffer chip. The present disclosure may adjust the first memory chip and the buffer chip of two different sizes to be a same size through the dummy chip. For example, the size of the micro-memory module and the size of the buffer chip may be same such that the wafer-level hybrid-bonding may be realized, and the efficiency of the hybrid-bonding, compared with single-chip bonding, may be greatly improved. Accordingly, a mass production and a high output rate may be achieved. In addition, the hybrid-bonding may also be performed between the first memory chips of every two adjacent layers, which may achieve a smaller spacing. Under the same density, increasing the number of vertical interconnections and increasing the number of data channels may improve the data throughput.

FIG. 20 illustrates another exemplary packaging structure according to various disclosed embodiments of the present disclosure. As shown in FIG. 20, an exemplary packaging structure 200 may include a buffer chip 210 and a plurality of micro-memory modules 280. The buffer chip 210 may be provided with a plurality of first conductive vias 211. The micro-memory modules 280 may be stacked on the buffer chip 210, and the orthographic projection of the memory micro-module 280 on the buffer chip 210 may coincide with the buffer chip 210. Each micro-memory module 280 may include a dummy chip 220 and a first stacked memory module 240. The dummy chip 220 may be provided with a groove body, the groove body may be provided with a first stacked memory module 240, and the first stacked memory module 240 may include a plurality of first memory chips 230 stacked in sequence. The first memory chips 230 may be provided with a plurality of second conductive vias 231 corresponding to and electrically connected to the plurality of first conductive vias 211. In this embodiment, both the first conductive via 211 and the second conductive via 231 may be TSVs, and the vertical electrical interconnection of the TSVs may be realized by using the TSV technology, which may reduce the packaging height.

Exemplarily, as shown in FIG. 20, a first passivation layer 232 and a first metal soldering pad 233 may be provided on the first surface of the first memory chip 230 facing away from the buffer chip 210, and the second surface of the first memory chip 230 facing the first buffer chip 210 may be provided with a second passivation layer 234 and a second metal soldering pad 235. In one embodiment, the first passivation layer 232 and the second passivation layer 234 in every two adjacent layers of the first memory chips 230 may be bonded and connected, and the first metal soldering pads 233 in the first memory chips 230 in every two adjacent layers may be bonded with the second metal soldering pad 235.

It should be noted that, in this embodiment, the materials of the first passivation layer 232 and the second passivation layer 234 may be silicon dioxide or silicon nitride, and the first metal soldering pad 233 and the second metal soldering pad 235 may be copper pads.

In one embodiment, as shown in FIG. 20, the surface of the buffer chip 210 facing the micro-memory module 280 may be provided with a third passivation layer 212 and a third metal soldering pad 213. The third passivation layer 212 may be bonded and connected to the second passivation layer 234 on the side of the first stacked memory module 240 facing the buffer chip 210, and the third metal soldering pad 213 may be bonded and connected to the second metal soldering pad 235 on the side of the first stacked memory module 240 facing the buffer chip 210.

It should be noted that, in this embodiment, the material of the third passivation layer 212 may be silicon dioxide or silicon nitride, and the third metal soldering pad 213 may be a copper pad.

In one embodiment, as shown in FIG. 20, an adhesive layer 260 may be further provided between the dummy chip 220 and the buffer chip 210 and between the sidewall of the groove body and the first stacked memory module 240. The adhesive layer 260 may further fix the first stacked memory module 240 in the groove body of the dummy chip 220.

Further, in one embodiment, as shown in FIG. 20, a plurality of bumps 270 may be provided on the surface of the buffer chip 210 facing away from the micro-memory module 280, and the plurality of bumps 270 may correspond to the plurality of first conductive vias 211. The packaging structure 200 may be electrically connected to outside through the plurality of bumps 270. In this embodiment, the bumps 270 may be copper-tin bumps.

In the packaging structure of the present disclosure, the hybrid-bonding connection between every two adjacent first memory chips and the hybrid-bonding connection between the micro-memory module and the buffer chip may realize the interconnection of ultra-fine pitches and greatly improve the output efficiency, and reduce the manufacturing cost. The first memory chip and the buffer chip of two different sizes may be adjusted to be the same size through the dummy chip, that is, the size of the micro-memory module and the buffer chip may be same, and the wafer-level hybrid-bonding may be realized. The efficiency of the hybrid-bonding may be higher than that of a single-chip bonding and should be greatly improved to achieve the mass production and the high yield.

FIG. 21 illustrates a flow chart of another exemplary packaging method of a multiple-stacked memory according to various disclosed embodiments of the present disclosure. As shown in FIG. 21, the exemplary packaging method S300 may include S310: providing a buffer chip, a plurality of first dummy chips, a second dummy chip, a third dummy chip, and a plurality of first memory chips. The first dummy chip may be provided with a first groove body and a plurality of first cooling through holes. The buffer chip may be provided with a plurality of first conductive vias, and the first memory chip may be provided with a plurality of second conductive vias corresponding to the plurality of first conductive vias.

Specifically, as shown in FIG. 36, a buffer chip 310, a plurality of first dummy chips 320, a second dummy chip 330, a third dummy chip 340 and a plurality of first memory chips 350 may be provided. The first dummy chip 320 may be provided with a groove body (not shown). The central area of the first dummy chip 320 may be provided with a first groove body (not shown), and a plurality of first cooling vias 321 may be disposed at the edge area of the first dummy chip 320. The buffer chip 310 may be provided with a plurality of first conductive vias 311, and the first memory chip 350 may be provided with a plurality of second conductive vias 351 corresponding to the plurality of first conductive vias 311. Both the first conductive via 111 and the second conductive via 351 may be TSVs. The vertical electrical interconnection of TSVs may be realized by using the TSV technology, which may reduce the packaging height. The first memory chip 350 may be a dynamic random access memory chip, or other memory chips, which are not specifically limited in this embodiment.

The packaging method S300 may also include S320: respectively fixing each of the first memory chips in the first groove body of the corresponding first dummy chip to form a plurality of first micro-memory modules.

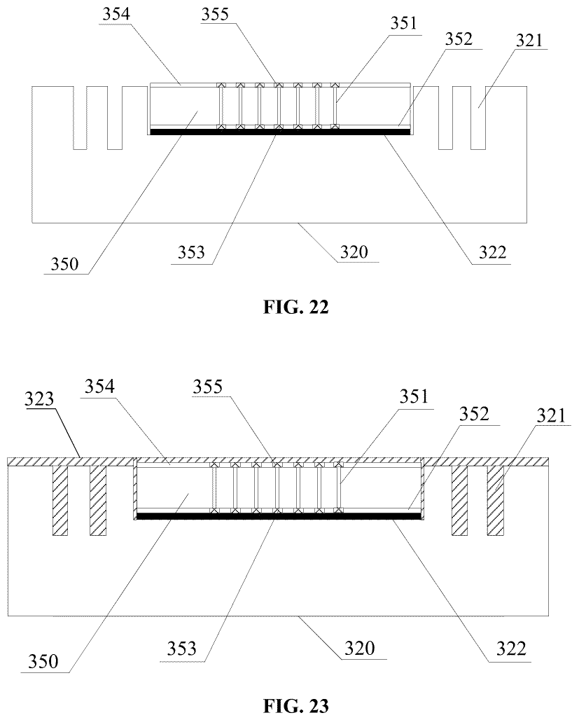

Specifically, as shown in FIG. 22, the first passivation layer 352 and the first metal soldering pad 353 may be provided on the first surface of the first memory chip 350 facing the buffer chip 310, and a second passivation layer 354 and a second metal soldering pad 355 may be disposed on the second surface of the first memory chip 350 facing away from the buffer chip 310.

It should be noted that, in this embodiment, the materials of the first passivation layer 352 and the second passivation layer 354 may be silicon dioxide or silicon nitride, or other materials that play a passivation role. In this embodiment, the material of the first metal soldering pad 353 and the second metal soldering pad 355 may be copper metal, or other metal materials, which are not specifically limited in this embodiment.

The process that each of the first memory chips is respectively fixed in the corresponding groove body of the first dummy chip to form the plurality of first micro-memory modules may include following steps.

First, a first adhesive layer may be formed between the bottom wall of the first groove body and the first surface of the first memory chip to fix the first memory chip in the first groove body.

Specifically, as shown in FIG. 22, a first adhesive layer 322 may be formed on the bottom wall of the first groove body and the first surface of the first memory chip 350. In this embodiment, the back surface of the first memory chip 350 may be fixed in the first groove body using the first adhesive layer 322. It should be noted that the size of the first groove body may be slightly greater than the size of the first memory chip 350, and the depth of the groove body may be smaller than the height of the first memory chip 350. For example, the surface of the first memory chip 350 may protrude beyond the surface of the dummy chip 320. When the surface of the first memory chip 350 protrudes from the surface of the first dummy chip 320, a plurality of first dummy chips 320 may be bonded and fixed.

Then, a second adhesive layer may be formed on the second surface of the first dummy chip and the first memory chip, and a portion of the second adhesive layer may be filled in the first cooling vias and the gap between the sidewall of the first groove body and the first memory chip.

Specifically, as shown in FIG. 23, a second adhesive layer 323 may be formed on the second surfaces of the first dummy chip 320 and the first memory chip 350. In this embodiment, the second adhesive layer 323 may be formed on the front surfaces of the first dummy chip 320 and the memory chip 350, and a portion of the second adhesive layer 323 may be filled into the first cooling vias 321 and the gap between the sidewall of the first groove body and the first memory chip 350. When the portion of the second adhesive layer 323 is filled in the gap between the sidewall of the first groove body and the first memory chip 350, the first memory chip 350 may be further fixed in the first groove body.

Then, the second adhesive layer on the second surface of the first memory chip may be completely removed to expose the second passivation layer and the second metal soldering pad, while retaining a portion of the second adhesive layer on the surface of the first dummy chip.

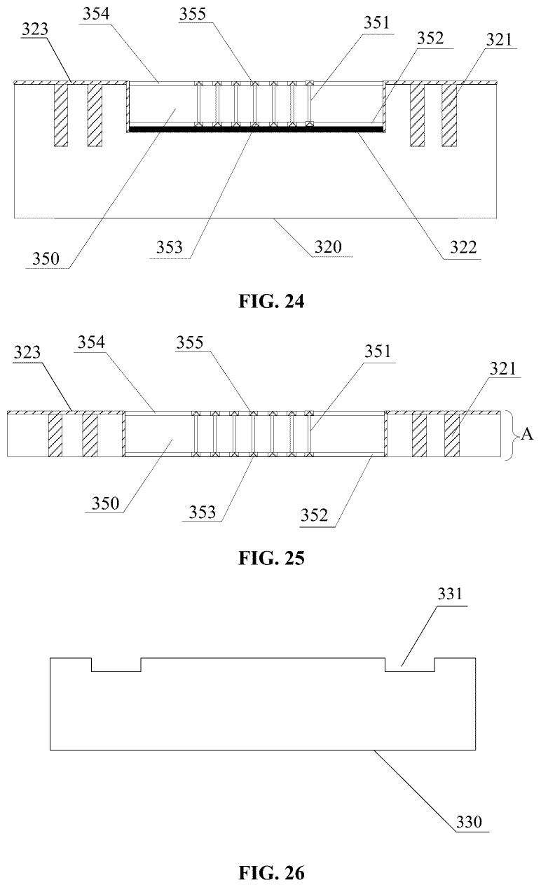

Specifically, as shown in FIG. 24, the second surface of the first memory chip 350 may be polished and chemically cleaned, and the second adhesive layer 323 on the second surface of the first memory chip 350 may be completely removed to expose the second passivation layer 354 and the second metal soldering pad 355 while retaining the portion of the second adhesive layer 323 on the surface of the first dummy 320. The portion of the second adhesive layer 323 remaining on the surface of the first dummy 320 may be flush with the second passivation layer 354.

Finally, the first adhesive layer on the first surface of the first memory chip may be removed to expose the first passivation layer, the first metal soldering pad and the first cooling vias to form the first micro-memory module.

Specifically, as shown in FIG. 25, the backside of the first dummy chip 320 may be grinded and polished to remove the silicon on the backside of the first dummy chip 320 and the first adhesive layer 322 on the first surface of the first memory chip 350 to expose the first passivation layer 352, the first metal soldering pads 353 and the plurality of first cooling vias 321, thus forming the first micro-memory module A by the combination of the first dummy chip 320 and the first memory chip 350.

Further, the packaging method S300 may include S330: performing an anodic bonding on the second dummy chip and the third dummy chip, and forming a second groove body in a second dummy chip at the position corresponding to the first groove body of the third dummy chip, and a second cooling via may be formed at the third dummy chip corresponding to the first cooling via. The second cooling via may be connected with the first cooling via.

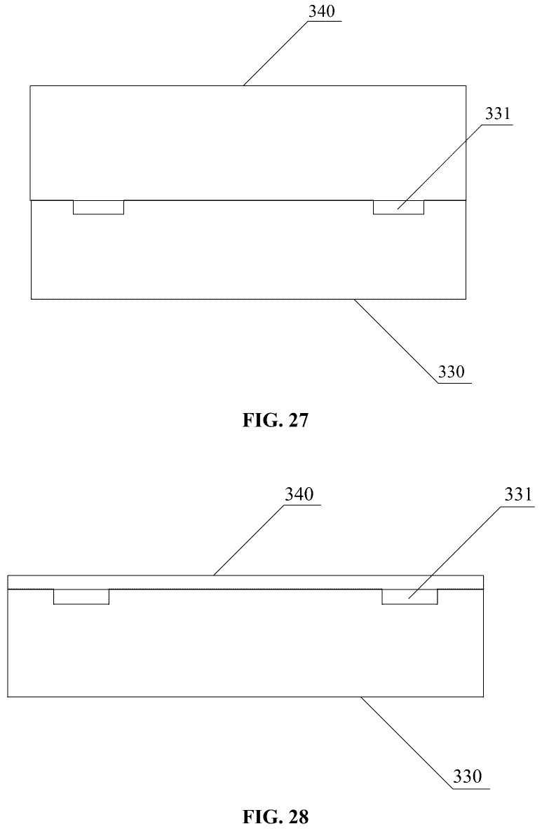

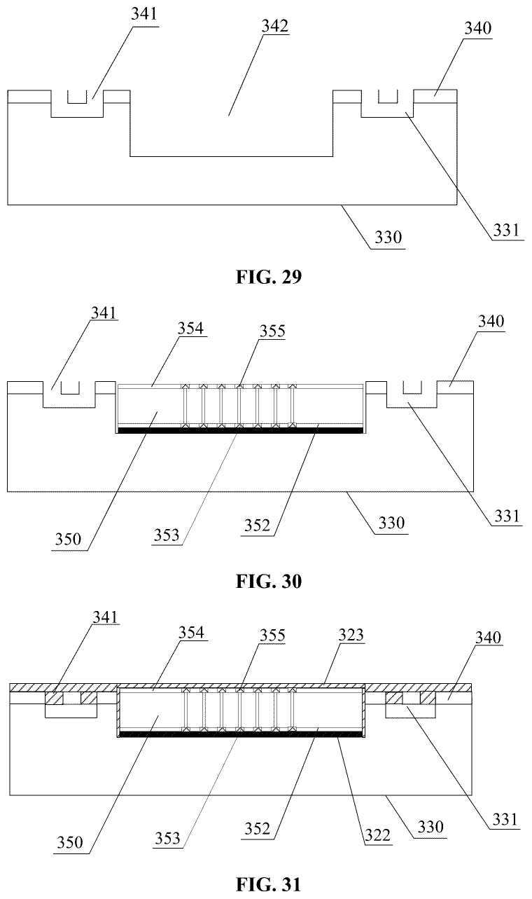

Specifically, as shown in FIG. 27, the second dummy chip 330 and the third dummy chip 340 may be anodic bonded, and then as shown in FIG. 28, the side of the third dummy chip 340 away from the second dummy chip 330 may be thinned according to the packaging requirements. As shown in FIG. 29, a second groove body 342 may be formed at a position of the thinned second dummy chip 230 corresponding to the first groove body of the third dummy chip 340 through an etching process, and a plurality of second cooling vias 341 may be formed at the position of the thinned third dummy chip 340 corresponding to the first cooling vias 321 through an etching process. The second cooling vias 341 may be connected with the first cooling vias 321.

In one embodiment, before the anodic bonding of the second dummy chip and the third dummy chip, the packaging method S300 may further include forming a cooling through groove on the second dummy chip. The cooling through-groove may be connected with the second cooling via.

Specifically, as shown in FIG. 26, through an etching process, a cooling through-groove 331 may be formed on the side of the second dummy chip 330 facing the first memory chip 350. The cooling through-groove 331 may be connected with the second cooling vias 341. Accordingly, the first cooling vias 321, the second cooling vias 341 and the cooling through-groove 331 together may form a plurality of cooling channels for the first memory chips, which may be configured as channels for the ingress and egress of the external cooling liquid to force cool the plurality of first memory chips 350 to improve the heat dissipation performance of the first memory chip 350.

Further, the packaging method S300 may include S340: fixing the first memory chip in the second groove body to form a second micro-memory module.

First, a first adhesive layer may be formed between the bottom wall of the second groove body and the first surface of the first memory chip to fix the first memory chip in the second groove body.

Specifically, as shown in FIG. 30, the first adhesive layer 322 may be formed on the bottom wall of the second groove body 342 and the first surface of the first memory chip 350. In one embodiment, the first adhesive layer 322 may fix the back surface of the first memory chip 350 in the second groove body 342. It should be noted that the size of the second groove body 342 may be slightly greater than the size of the first memory chip 350, and the depth of the second groove body 342 may be smaller than the height of the first memory chip 350. For example, the surface of the first memory chip 350 may protrude from the surface of the third dummy 340. When the surface of the first memory chip 350 protrudes from the surface of the third dummy chip 340, a plurality of first dummy chips 320 and third dummy chips 340 may be bonded and fixed.

Then, the second adhesive layer may be formed on the third dummy chip and the second surface of the first memory chip, and a portion of the second adhesive layer may be filled to the second cooling via and the gap between the sidewall of the second groove body and the first memory chip.

Specifically, as shown in FIG. 31, a second adhesive layer 323 may be formed on the second surfaces of the third dummy chip 340 and the first memory chip 350, and a portion of the second adhesive layer 323 may be filled into the second cooling vias 341 and the gap between the sidewall of the second groove body 342 and the first memory chip 350. A portion of the second adhesive layer 323 may be filled in the gap between the sidewall of the second groove body 342 and the first memory chip 350, and the first memory chip 350 may be further fixed in the second groove body 342.

Then, the second adhesive layer on the second surface of the first memory chip may be completely removed to expose the second passivation layer and the second metal soldering pad, while retaining a portion of the second adhesive layer on the surface of the third dummy chip.

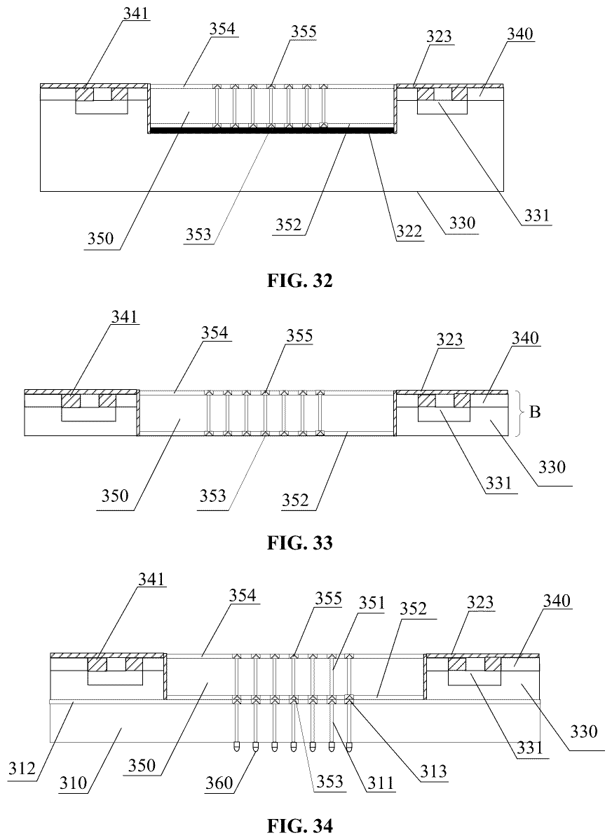

Specifically, as shown in FIG. 32, the second surface of the first memory chip 350 may be polished and chemically cleaned, and the second adhesive layer 323 on the second surface of the first memory chip 350 may be completely removed to expose the second passivation layer 354 and the second metal soldering pads 355 while retaining the portion of the second adhesive layer 323 on the surface of the third dummy chip 340. The portion of the second adhesive layer 323 remaining on the surface of the third dummy chip 340 may be flush with the second passivation layer 354.

Finally, the first adhesive layer on the first surface of the first memory chip may be removed to expose the first passivation layer and the first metal soldering pad to form the second micro-memory module.

Specifically, as shown in FIG. 33, the backside of the third dummy chip 340 may be grinded and polished to remove the silicon on the backside of the third dummy chip 340 and the first adhesive layer 322 on the first surface of the first memory chip 350 to expose the first passivation layer 352. The first metal soldering pads 353 and the plurality of second cooling vias 341 may thus form a second micro-memory chip module B with the combination of the second dummy chip 330, the third dummy chip 340 and the first memory chip 350.

Further, the packaging method S300 may also include S350: hybrid-bonding and stacking the second micro-memory module and the plurality of first micro-memory modules on the buffer chip in sequence. The orthographic projections of the second micro-memory module and the first memory of the micro-module on the buffer chip may all coincident with the buffer chip.

Specifically, as shown in FIG. 34, a third passivation layer 312 and a third metal soldering pad 313 may be disposed on the side of the buffer chip 310 facing the second micro-memory module B. In one embodiment, the material of the third passivation layer 312 may be silicon dioxide or silicon nitride, and the material of the third metal soldering pad 313 may be metal copper. The material of the third metal soldering pads 313 may not be specifically limited in this embodiment.

The process for sequentially hybrid-bonding and stacking of the second micro-memory module and the plurality of first micro-memory modules on the buffer chip may include following steps.

First, the first passivation layer of the second micro-memory module may be bonded to the third passivation layer on the buffer chip, and the first metal soldering pad of the second micro-memory module may be bonded to the third metal soldering pad of the buffer chip.

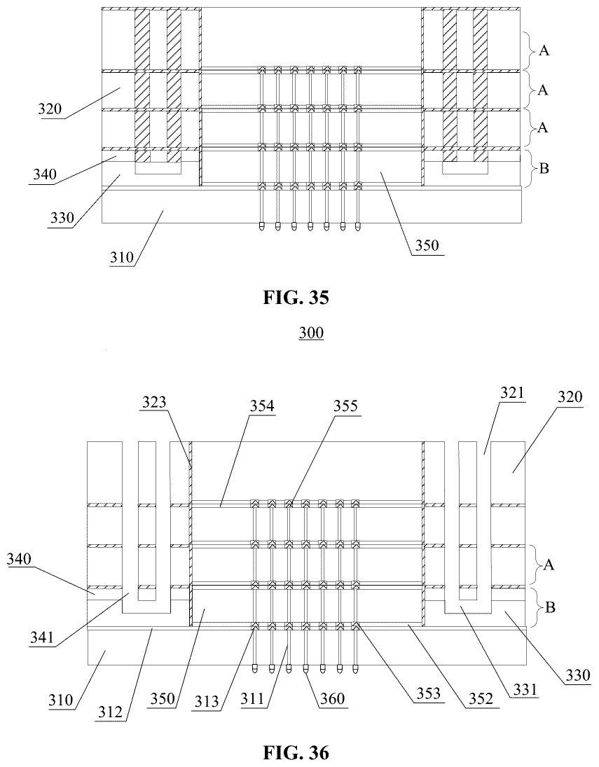

Specifically, as shown in FIG. 34 and FIG. 35, the first passivation layer 352 of the second-layer micro-memory module B and the third passivation layer 312 on the buffer chip 310 may be hybrid-bonded by a thermal compression bonding process. The first metal soldering pad 353 of the second micro-memory module B may be aligned with the third metal soldering pad 313 on the buffer chip 310, and the bonding connection may be realized by the thermal expansion of copper through the high temperature compression. The second adhesive layer 323 retained on the surface of the third dummy chip 340 in the second micro-memory module B may further fix the second micro-memory module B on the buffer chip 310.

Next, the first passivation layer of the bottom first micro-memory module may be bonded with the second passivation layer of the second micro-memory module, and the first metal soldering pad of the bottom first micro-memory module may be bonded to the second metal soldering pad of the second micro-memory module.

Specifically, as shown in FIG. 35 and FIG. 36, the first passivation layer 352 of the bottom first micro-memory module A and the second passivation layer 354 of the second micro-memory module B may be hybrid-bonded under conditions of heating and pressing. The first metal soldering pads 353 of the bottom first micro-memory module A and the second metal soldering pads 155 of the second micro-memory module B may be hybrid-bonded under heating and pressing conditions.

Finally, the remaining layers of the first micro-memory modules may be hybrid-bonded and stacked on the second micro-memory modules in sequence. The first passivation layer in every two adjacent layers of first micro-memory modules may be bonded with the second passivation layer; and the first metal soldering pads in every two adjacent layers of first micro-memory modules may be bonded with the second metal soldering pads.

Specifically, as shown in FIG. 35 and FIG. 36, the remaining layers of the first micro-memory modules A may be hybrid-bonded and stacked on the second micro-memory modules B in sequence. The first passivation layer 352 of one of every two adjacent layers of first micro-memory modules A and the second passivation layer 354 of the other of them may be hybrid-bonded under heating and pressing conditions. The first metal soldering pad 353 of one of every two adjacent layers of the first micro-memory module A and the second metal soldering pad 355 of the other of them may be hybrid-bonded under heating and pressing conditions.

That is to say, as shown in FIG. 35, the second micro-memory module B and the buffer chip 310 may be hybrid-bonded, the bottom-layer first micro-memory module A and the second micro-memory module B may be hybrid-bonded, and the second-layer first memory micro-module A and the second memory micro-module B may be hybrid-bonded. The micro-memory module A may be arranged on the first layer of first micro-memory module A and may be bonded with the first-layer micro-memory module A, and by analogy, the first micro-memory module A of each layer may be bonded and stacked on the second micro-memory module B in turn.

As shown in FIG. 36, only the side of the first micro-memory module A facing the buffer chip 310 may be provided with the first passivation layer 352 and the first metal soldering pad 353, because the first micro-memory module A on the top layer may have the protective function to the packaging structure, the thickness of the first micro-memory module A on the top layer may be thicker than that of other first micro-memory modules A, and the first memory chip 350 may not be provided with a second conductive via.

The first memory chips 350 and the first memory chips 350 and the buffer chip 310 may be bonded by the hybrid bonding, and a smaller spacing may be achieved. Under the same density, increasing the number of vertical interconnections and increasing the number of data channels may increase the number of data channels. Accordingly, the data throughput may be improved.

As shown in FIG. 34, FIG. 35 and FIG. 36, the orthographic projection of the first micro-memory module A on the buffer chip 110 may coincide with the buffer chip 110, and the orthographic projection of the second micro-memory module B on the buffer chip 110 may coincide with the buffer chip 110. For example, the size of the first micro-memory module A and the second micro-memory module B may be same as that of the buffer chip 110. When the size of the first memory chip 350 is adjusted to be same as the size of the buffer chip 110 through the first dummy chip 120, the second dummy chip 130 and the third dummy chip 140, the wafer-level hybrid-bonding may be realized, and the efficiency of hybrid-bonding may be greatly improved compared with single-chip bonding while achieving high-density interconnection. Accordingly, the mass production may be realized.

In one embodiment, after the hybrid-bonding and stacking of the second micro-memory module and the plurality of first micro-memory modules on the buffer chip in sequence, the method may further include removing the second adhesive layer in the first cooling via and the second cooling via.

Specifically, as shown in FIG. 36, the second adhesive layer 323 in the first cooling via 321 and in the second cooling vias 341 may be removed by laser and cleaning agent to form a hollow cooling channel. The hollow cooling channel may be configured as an external cooling liquid inlet and outlet channel to perform a forced cooling. Then, a dicing process may be performed to form independent chips. The dicing process may be performed after forming a plurality of bumps 260 to form a plurality of independent memory packaging structures.

In this embodiment, a plurality of bumps 260 may be provided on the side of the buffer chip 210 away from the second micro-memory module B, and the plurality of bumps 260 may correspond to and may be electrically connected to the plurality of conductive vias 111.

In the multi-layer stacked memory packaging method of the present disclosure, the first memory chip may be adjusted to be consistent with the size of the buffer chip through the first dummy chip, the second dummy chip and the third dummy chip. All the buffer chips may be connected by a hybrid-bonding process, which may greatly improve the interconnection density. Interconnected first cooling vias, second cooling vias and cooling channels may be formed in the first, second and third dummy chips to implement the forced cooling of the first memory chips, the heat dissipation performance of the memory chip may be greatly improved, and the characteristics of HBM products may be improved through the synergistic improvement of electrical-thermal performance.

FIG. 36 illustrates another exemplary multi-layer stacked memory packaging structure according to various disclosed embodiments of the present disclosure. As shown in 36, the packaging structure 300 may include a buffer chip 310 and a plurality of first micro-memory modules A and second micro-memory modules B. The buffer chip 310 may be provided with a plurality of first conductive vias 311. The second micro-memory modules B may be hybrid-bonded and stacked on the buffer chip 310. The plurality of first micro-memory modules A may be sequentially hybrid-bonded and stacked on the second micro-memory modules B and the orthographic projections of the first micro-memory module A and the second micro-memory module B on the buffer chip 310 may coincide with the buffer chip 310. That is, the size of the first micro-memory module A and the second micro-memory module B may be same as that of the buffer chip 310.

Each first micro-memory module A may include a first memory chip 350 and a first dummy chip 320 provided with a first groove body and a plurality of first cooling vias 321. The first groove body may be provided with a first memory chip 350; and the first memory chip 350 may be provided with a plurality of second conductive vias 351 corresponding to and electrically connected to the plurality of first conductive vias 311.

Both the first conductive via 311 and the second conductive via 351 may be TSVs. The vertical electrical interconnection of TSVs may be realized by using the TSV technology, which may reduce the packaging height. The first memory chip 350 may be a dynamic random access memory chip, or other memory chips, which are not specifically limited in this embodiment.

The second micro-memory module B may include a first memory chip 350, a second dummy chip 330, and a third dummy chip 340 sandwiched between the first dummy chip 320 and the second dummy chip 330. The second dummy chip 330 and the third dummy chip 340 may be provided with a second groove body corresponding to the first groove body. The first memory chip 350 may be provided in the second groove body, and the third dummy chip 340 may be provided with a second cooling via 321 corresponding to and connected with the second cooling via 341.

In one embodiment, as shown in FIG. 36, the second dummy chip 330 may be provided with a cooling via 331, and the cooling via 331 may be connected with the second cooling via 341. In this way, the first cooling via 321, the second cooling via 341 and the cooling groove 331 together may form a plurality of cooling channels for the first memory chips 350, which may be configured as channels for the ingress and egress of the external cooling liquid to perform the forced cooling to the plurality of first memory chips 350; and improve the heat dissipation performance of the first memory chips 350.

In one embodiment, as shown in FIG. 36, the first passivation layer 352 and the first metal soldering pad 353 may be provided on the first surface of the first memory chip 350 facing the buffer chip 310, and the second passivation layer 354 and the second metal soldering pad 355 may be provided on the second surface of the first memory chip 350 facing away from the buffer chip 110.

The first passivation layer 352 and the second passivation layer 354 in every two adjacent layers of first micro-memory module A may be bonded by the hybrid-bonding, and the first metal soldering pad 353 and the second metal soldering pad 153 in every two adjacent layers of second micro-memory module B may be bonded by the hybrid-bonding.

In one embodiment, the second passivation layer 354 in the second micro-memory module B may be bonded with the first passivation layer 352 in the bottom layer first memory micro-module A by the hybrid-bonding, and the second metal pads 355 in the second micro-memory module B may be bonded with the first metal soldering pads 353 in the bottom layer first micro-memory module A by the hybrid-bonding.

In one embodiment, as shown in FIG. 36, the surface of the buffer chip 310 facing the second micro-memory module B may be provided with a third passivation layer 312 and a third metal soldering pad 313. The third passivation layer 312 may be bonded with the first passivation layer 352 in the second micro-memory module B by the hybrid-bonding, and the third metal soldering pad 313 may be bonded with the first metal soldering pad 353 in the second micro-memory module B by the hybrid-bonding.

It should be noted that, in this embodiment, the materials of the first passivation layer 352, the second passivation layer 354 and the third passivation layer 312 may be silicon dioxide or silicon nitride, or other materials. and this embodiment does not make specific limitations. The materials of the first metal soldering pad 353, the second metal soldering pad 355 and the third metal soldering pad 313 may be copper, and may also be other metal materials, which are not specifically limited in this embodiment.

In this embodiment, as shown in FIG. 36, a plurality of bumps 360 may be provided on the side of the buffer chip 310 away from the second micro-memory module B, and the plurality of bumps 360 may correspond to and electrically connected the plurality of conductive vias 311.

In the packaging structure of the present disclosure, the first memory chip may be adjusted to have a size same as that of the buffer chip through the first dummy chip, the second dummy chip and the third dummy chip. The first memory chips and the first memory chip and the buffer chip may be bonded by a hybrid bonding, which may greatly improve the interconnection density. The first, second, and third dummy chip may be provided with a first cooling via, a second cooling via, and a cooling through groove that may be connected with each other and may be configured as an inlet and outlet channel for external cooling liquid to achieve a forced cooling of the first memory chips. Thus, the heat dissipation performance of the memory chip may be significantly improved, and the product characteristics of the memory chip may be enhanced through the synergistic improvement of electrical-thermal performance.

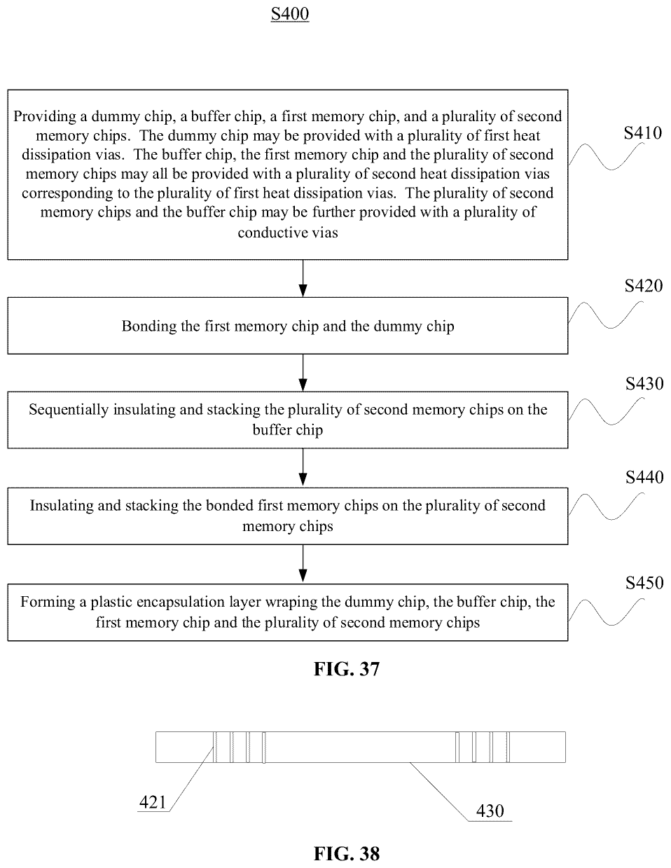

FIG. 37 illustrates a flowchart of another exemplary packaging method of a multi-layer stacked memory consistent with various disclosed embodiments of the present disclosure. As shown in FIG. 37, an exemplary packaging method S400 of a multi-layer stacked high-bandwidth memory may include S410: providing a dummy chip, a buffer chip, a first memory chip, and a plurality of second memory chips. The dummy chip may be provided with a plurality of first heat dissipation vias. The buffer chip, the first memory chip and the plurality of second memory chips may all be provided with a plurality of second heat dissipation vias corresponding to the plurality of first heat dissipation vias. The plurality of second memory chips and the buffer chip may be further provided with a plurality of conductive vias.

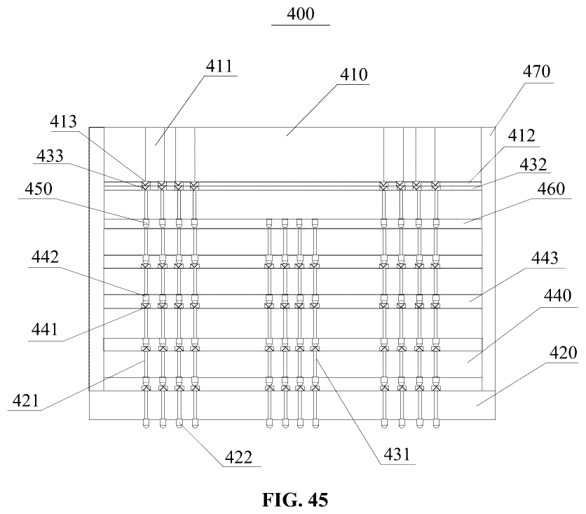

Specifically, as shown in FIG. 45, a dummy chip 410, a buffer chip 420, a first memory chip 430 and a plurality of second memory chips 440 may be provided. The dummy chip 410 may be provided with a plurality of first heat dissipation vias 411, and the dummy chip 410 may be a dedicated heat dissipation chip. The buffer chip 420, the first memory chip 430 and the plurality of second memory chips 440 may all be provided with a plurality of second heat dissipation vias 421 corresponding to the plurality of first heat dissipation vias 411. The second memory chip 440 and the buffer chip 420 may also be provided with a plurality of conductive vias 431.

In one embodiment, as shown in FIGS. 40-42, the cross-sectional dimension of the first heat dissipation via 411 may be not smaller than the cross-sectional dimension of the second heat dissipation via 421. That is, the cross-sectional size of the first heat dissipation via 411 may be equal to or greater than the cross-sectional size of the second heat dissipation via 421. Further, in this embodiment, the cross-sectional size of the first heat dissipation via 411 may be larger than the cross-sectional size of the second heat dissipation via 421, and the cross-sectional size of the first heat dissipation vias 411 may be approximately three times of the cross-sectional size of the second heat dissipation vias 421. The cross-sectional size of the first heat dissipation via 411 may also be larger than that of the conductive via 431. When a plurality of large-sized first heat dissipation vias 411 are provided on the dummy chip 410, the plurality of large-sized first heat dissipation vias 411 may be directly connected to an external heat sink or an active heat dissipation device to help the heat dissipation of the high-bandwidth memory and the heat dissipation performance of the entire high-bandwidth memory may be improved.

In one embodiment, as shown in FIGS. 43-45, the first heat dissipation vias 411 and the second heat dissipation vias 421 may be distributed on the periphery of the conductive vias 431. That is to say, the conductive vias 431 may be located in the middle of the first memory chip 430 and the buffer chip 420, and the conductive vias 431 may play a signal transmission role. The first heat dissipation vias 411 and the second heat dissipation vias 421 may be distributed in the periphery of the conductive via 431 and may mainly play the role of heat dissipation. It should be noted that, as shown in FIG. 43, FIG. 44 and FIG. 45, the first heat dissipation vias 411, the second heat dissipation vias 421 and the conductive vias 431 may be distributed at equal intervals, and may also be distributed at unequal intervals; and no specific limitation is made.

In one embodiment, the first heat dissipation via 411, the second heat dissipation via 421 and the conductive via 431 may all be TSVs. The first heat dissipation vias 411 and the second heat dissipation vias 421 may use through-silicon vias to provide metal heat dissipation channels such that the high-bandwidth memory may have higher heat dissipation characteristics. The second memory chip 440 and the buffer chip 420 may be electrically connected to achieve a better signal transmission.

The packaging method S400 may also include S420: bonding the first memory chip and the dummy chip.

In one embodiment, as shown in FIG. 40, the first memory chip 430 may bonded to the dummy chip 410. For example, the first memory chip 430 and the dummy chip 410 may be hybrid-bonded. The hybrid-bonding of the first memory chip 430 and the dummy chip 410 may reduce the package height of the high-bandwidth memory.

It should be noted that when the thickness of the first memory chip 430 is thin enough to expose the second heat dissipation vias 421 disposed thereon, the first memory chip 430 may not need to be thinned. However, when the thickness of the first memory chip 430 is too thick to expose the second heat dissipation vias 421 disposed thereon, the first memory chip 430 may need to be thinned. In this embodiment, as shown in FIG. 38, the first memory chip 430 needs to be thinned to expose the plurality of second heat dissipation vias 421 for the heat dissipation.

It should be further noted that, before hybrid-bonding the first memory chip 430 and the dummy chip 410, as shown in FIG. 40, the first passivation layer 412 and the first metal soldering pad 413 may be disposed on the front surface of the dummy chip 410. In this embodiment, the first passivation layer 412 may be a silicon dioxide passivation layer, and the first metal soldering pad 413 may be a copper pad, which is not specifically limited in this embodiment.

The process for hybrid-bonding the first memory chip and the dummy chip may include following steps.

First, a second passivation layer and a second metal soldering pad may be formed on the surface of the first memory chip facing the dummy chip.

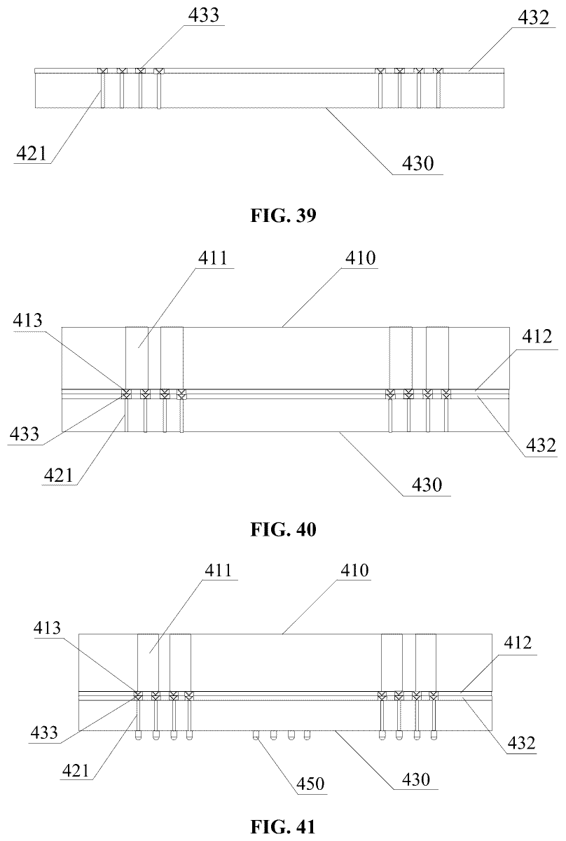

Specifically, as shown in FIG. 39, the second passivation layer 432 and the second metal soldering pad 433 may be formed on the surface of the first memory chip 430 facing the dummy 410. For example, the second passivation layer 432 and second metal soldering pads 433 may be formed on the backside of the first memory chip 430. In this embodiment, the second passivation layer 432 may be a silicon dioxide passivation layer, and the second metal soldering pad 133 may be a copper pad, which is not specifically limited in this embodiment.

Second, the second passivation layer may be bonded with the first passivation layer; and the second metal soldering pad may be bonded with the first metal soldering pad.

Specifically, as shown in FIG. 40, in one embodiment, the second passivation layer 432 and the first passivation layer 412 may be first bonded. After the second passivation layer 432 is bonded with the first passivation layer 412, a high temperature compression process may be performed, and the second metal pad 133 and the first metal pad 113 may be bonded by the thermal expansion of copper.

Further, the packaging method S400 may include S430: sequentially insulating and stacking the plurality of second memory chips on the buffer chip.

Specifically, as shown in FIG. 43, a plurality of second memory chips 440 may be sequentially insulated and stacked on the buffer chip 420 by a thermal compression bonding process. Other processes may also be used, which are not specifically limited in this embodiment. The surface of the second memory chip 440 facing away from the buffer chip 420 may be provided with a third metal soldering pad 441, and a plurality of first conductive bumps 442 may be provided on the third metal soldering pad 441. Each of the first conductive bumps 442 may correspond to the second heat dissipation vias 421 and the conductive vias 431 of the second memory chip 440, respectively. An insulating layer 443 may be disposed between every two adjacent second memory chips 440, and the insulating layer 443 may wrap the third metal soldering pad 441 and the plurality of first conductive bumps 442. In this embodiment, the third metal soldering pad 441 may be a copper pad, the insulating layer 442 may be a non-conductive adhesive film, and the plurality of first conductive bumps 442 may be copper-tin bumps, which are not specifically limited in this embodiment.

As shown in FIG. 43, FIG. 44 and FIG. 45, the surface of the buffer chip 420 facing away from the second memory chip 440 may be provided with a plurality of second conductive bumps 422. The heat dissipation vias 421 may correspond to the conductive vias 431. In this embodiment, the plurality of second conductive bumps 422 may be copper-tin bumps.

In one embodiment, before the plurality of second memory chips are sequentially insulated and stacked on the buffer chip, the packaging method S400 may also include following steps.

First, a plurality of bumps may be formed on the surface of the first memory chip facing away from the dummy chip. The plurality of bumps may correspond to the plurality of conductive vias, respectively.

Specifically, as shown in FIG. 41, a plurality of bumps 450 may be formed on the surface of the first memory chip 430 facing away from the dummy chip 410. The plurality of bumps 450 may correspond to the plurality of conductive vias 431, respectively. The first memory chip 430 may be electrically connected with the plurality of second memory chips 440 through the plurality of bumps 450. In this embodiment, the plurality of bumps 450 may be copper-tin bumps.

Next, a non-conductive adhesive film may be formed on the plurality of bumps, and the non-conductive adhesive film may wrap the plurality of bumps.

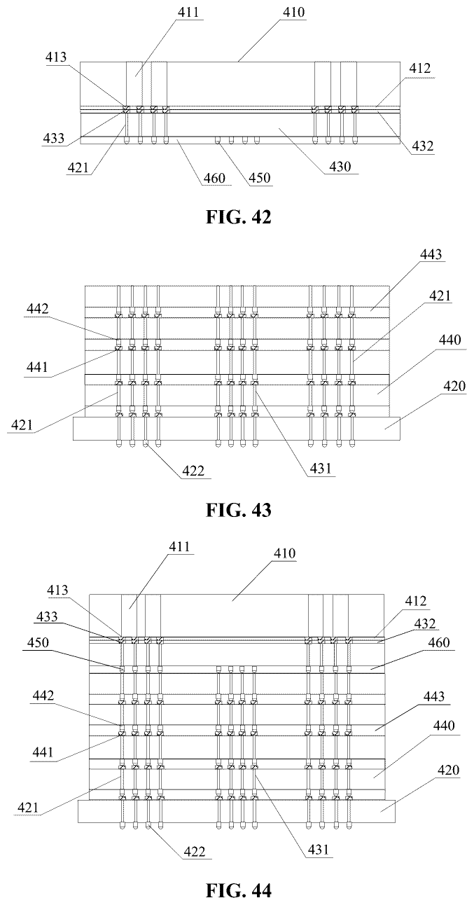

Specifically, as shown in FIG. 42, a non-conductive adhesive film 460 may be formed on the plurality of bumps 450, and the non-conductive adhesive film 460 may wrap the plurality of bumps 450 to play an insulating role.

It should be noted that, during the packaging process, multiple groups of second memory chips 440 may need to be disposed on the buffer chip 420 at the same time, and each group of second memory chips 440 may include a plurality of second memory chips 440 stacked in sequence. After the multiple groups of memory chips 440 are disposed on the buffer chip 420, they may need to be diced to form independent chip assemblies. Each chip assembly may include the buffer chip 420 and a plurality of second memory chips 440 stacked on the buffer chip 420 in sequence. A corresponding packaging step may then be performed for each individual chip assembly.

It should be noted that, the plurality of second memory chips 440 may also be sequentially insulated and stacked on the substrate, and may be connected to the outside through conductive vias and soldering balls provided on the substrate. After the plurality of second memory chips 440 are sequentially insulated and stacked on the substrate, the following packaging steps may be continued.

As shown in FIG. 37, a step S440 may include insulating and stacking the bonded first memory chips on the plurality of second memory chips.

Specifically, as shown in FIG. 44, the bonded first memory chips 430 may be insulated and stacked on a plurality of second memory chips 440. The non-conductive adhesive film 460 between the first memory chip 430 and the plurality of second memory chips 440 may play an insulating role. As shown in FIG. 44, the high-bandwidth memory may be sequentially composed of a buffer chip 410, a plurality of second memory chips 440, a first memory chip 430 and a dummy chip 410 from bottom to top. The top dummy chip 410 may be a dedicated heat dissipation chip.

As shown in FIG. 37, a step S450 may include forming a plastic encapsulation layer. The plastic encapsulation layer may wrap the dummy chip, the buffer chip, the first memory chip and the plurality of second memory chips.

Specifically, as shown in FIG. 45, a plastic encapsulation layer 470 may be formed, and the plastic encapsulation layer 470 may wrap the dummy chip 410, the buffer chip 420, the first memory chip 430 and the plurality of second memory chips 440. The plastic encapsulation method may be a vacuum lamination method or a traditional plastic encapsulation process, which is not specifically limited in this embodiment. After the plastic packaging is completed, a dicing process may be performed to form the final independent multi-layer stacked high-bandwidth memory packaging structure.

The multi-layer stacking high-bandwidth memory packaging method of the present disclosure may include bonding a first memory chip and a dummy chip, insulating and stacking a plurality of second memory chips on the buffer chip in sequence, and bonding the bonded first memory chips to the buffer chip. A memory chip may be insulated and stacked on a plurality of second memory chips, and the use of dummy chip may ensure the sufficient mechanical protection for the first memory chip and the plurality of second memory chips. At the same time, a plurality of first heat dissipation vias may be arranged on the dummy chip to provide heat dissipation channels for the high-bandwidth memory, and the plurality of first heat dissipation vias may be directly connected to external heat sinks or active heat dissipation devices to improve the heat dissipation performance of the entire high-bandwidth memory. Accordingly, the performance of broadband memory may be further improved.

FIG. 45 illustrates another exemplary packaging structure of a multi-layer stacked memory according to various disclosed embodiments of the present disclosure. As shown in FIG. 4-10, an exemplary packaging structure 400 of multi-layer stacked high-bandwidth memory may include a dummy chip 410, a buffer chip 420, a first memory chip 430, a plastic encapsulation layer 470 and a plurality of second memory chip 440.

The plurality of second memory chips 440 may be stacked on the buffer chip 420. It should be noted that, the plurality of second memory chips 440 may also be stacked on the substrate and connected to outside through electrical vias and soldering balls on the substrate.

The first memory chip 430 may be disposed on a side of the plurality of second memory chips 440 facing away from the buffer chip 420.

The dummy chip 410 may be bonded and connected to the side of the first memory chip 430 facing away from the buffer chip 420 through a bonding structure (not shown in the figure). In one embodiment, the dummy chip 410 may be bonded with the side of the first memory chip 430 facing away from the buffer chip 420 through the bonding structure.

The plastic encapsulation layer 470 may wrap the dummy chip 410, the buffer chip 420, the first memory chip 430 and the plurality of second memory chips 440.

The dummy chip 410 may be provided with a plurality of first heat dissipation vias 411. The buffer chip 420, the first memory chip 430 and the plurality of second memory chips 440 may all be provided with a plurality of second heat dissipation vias 421 corresponding to the plurality of first heat dissipation vias 211. The plurality of second memory chips 440 and the buffer chips 420 may also be provided with a plurality of conductive vias 431. When the plurality of first heat dissipation vias 111 are connected to the plurality of second heat dissipation vias 421, the heat dissipation of the first memory chip 430 and the plurality of second memory chips 440 may be improved.

In one embodiment, as shown in FIG. 45, the cross-sectional dimension of the first heat dissipation via 411 may not be smaller than the cross-sectional dimension of the second heat dissipation via 421. That is, the cross-sectional size of the first heat dissipation via 411 may be equal to or greater than the cross-sectional size of the second heat dissipation via 421. In one embodiment, the cross-sectional size of the first heat dissipation via 411 may be larger than the cross-sectional size of the second heat dissipation via 421, and the cross-sectional size of the first heat dissipation via 411 may be approximately three times larger than that of the second heat dissipation vias 421. Further, the cross-sectional dimension of the first heat dissipation via 111 may be larger than that of the conductive via 431. When the large-sized first heat dissipation via 411 is provided on the dummy chip 110, it may be directly connected to an external heat sink or an active heat dissipation device to help the high-bandwidth memory to dissipate heat and improve the heat dissipation performance of the entire high-bandwidth memory.

In one embodiment, as shown in FIG. 45, both the first heat dissipation vias 411 and the second heat dissipation vias 421 may be distributed on the periphery of the conductive vias 431. That is to say, the conductive vias 431 may be located in the middle of the chip, and the conductive vias 431 may play a role in signal transmission. The first heat dissipation vias 411 and the second heat dissipation vias 421 may be distributed on the periphery of the conductive vias 431 and mainly play a role heat dissipation. It should be noted that, as shown in the figure, the first heat dissipation vias 411, the second heat dissipation vias 421 and the conductive vias 431 may be distributed at equal intervals, or may be distributed at unequal intervals, which are not specifically limited in this embodiment.

In one embodiment, the first heat dissipation via 411, the second heat dissipation via 421 and the conductive via 431 may all be TSVs. The first heat dissipation vias 411 and the second heat dissipation vias 421 may utilize the through-silicon vias to provide the metal heat dissipation channels such that the high-bandwidth memory may have higher heat dissipation characteristics. The second memory chip 440 and the buffer chip 420 may be electrically connected to achieve better signal transmission.

In one embodiment, as shown in FIG. 45, the bonding structure may include a first passivation layer 412 and a first metal soldering pad 413 disposed on the surface of the dummy chip 410 facing the first memory chip 430, and a second passivation layer 432 and a second metal soldering pad 433 on the side of the first memory chip facing the surface of the dummy chip 410.

The first passivation layer 412 may be bonded to the second passivation layer 432, and the first metal soldering pad 413 may be bonded to the second metal soldering pad 433. In this embodiment, both the first passivation layer 412 and the second passivation layer 432 may be silicon dioxide passivation layers, and both the first metal soldering pad 413 and the second metal soldering pad 433 may be copper pads.

In one embodiment, as shown in FIG. 45, the surface of the first memory chip 430 facing away from the dummy chip 410 may be provided with a plurality of bumps 450. The plurality of bumps 450 may be respectively corresponding to the plurality of conductive vias 431.

In the packaging structure of the present disclosure, by arranging a dummy chip on the first memory chip, and setting a plurality of first heat dissipation vias on the dummy chip, a mechanical protection for the high-bandwidth memory may be improved and the heat dissipation performance may be enhanced.

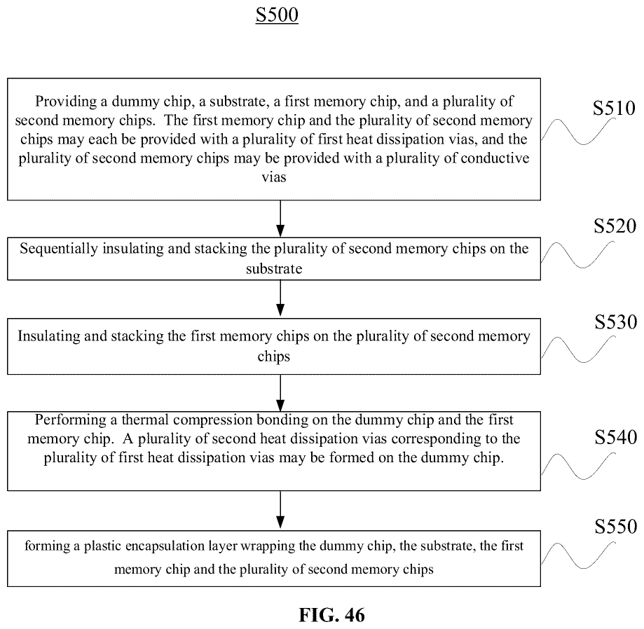

FIG. 46 illustrates a flow chart of another exemplary packaging method of a multi-layer stacked memory according to various disclosed embodiments of the present disclosure. As shown in FIG. 46, the packaging method S500 may include S510: providing a dummy chip, a substrate, a first memory chip, and a plurality of second memory chips. The first memory chip and the plurality of second memory chips may each be provided with a plurality of first heat dissipation vias, and the plurality of second memory chips may be provided with a plurality of conductive vias.

Specifically, as shown in FIG. 53, a dummy chip 510, a substrate 520, a first memory chip 530 and a plurality of second memory chips 540 may be provided. The first memory chip 530 and the plurality of second memory chips 540 may be provided with multiple first heat dissipation vias 521 and the plurality of second memory chips 140 may be provided with a plurality of conductive vias 531.

The packaging method 500 may also include S520: sequentially insulating and stacking the plurality of second memory chips on the substrate.

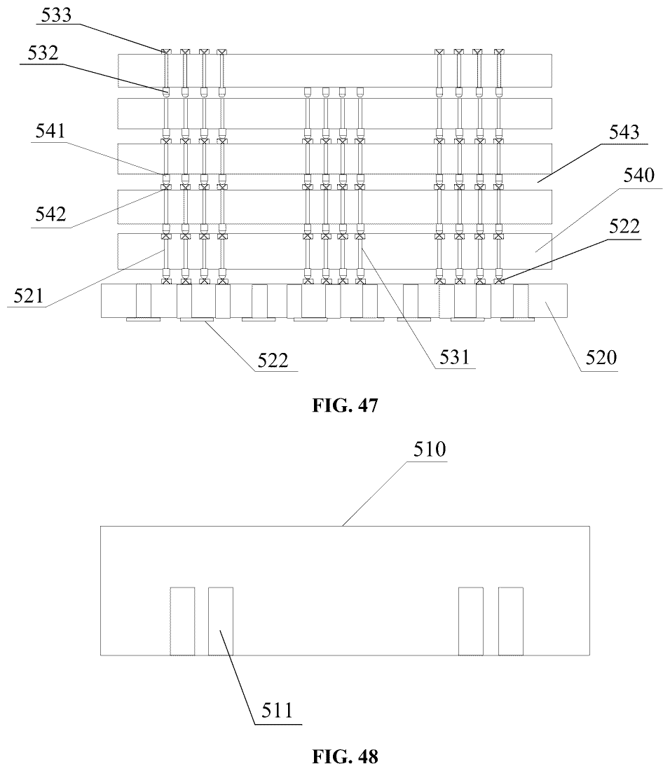

Specifically, as shown in FIG. 47, a plurality of first bumps 541 may be provided on the surface of the second memory chip 540 facing the substrate 520, and first soldering pads 542 may be provided on the surface of the second memory chip 540 facing away from the substrate 520. The surface of the substrate 520 facing the second memory chip 540 may be provided with the second soldering pads 522. The first bumps 541 may correspond to the first soldering pads 442 one-to-one.

The process for sequentially insulating and stacking the plurality of second memory chips on the substrate may include following steps.

First, the first bumps of the bottom layer of the second memory chip may be bonded to the second soldering pads by a thermal compression bonding process.

Specifically, as shown in FIG. 47, the first bumps 141 of the bottom layer second memory chip 540 and the second metal soldering pads 522 on the substrate 520 may be thermally pressed and welded.

Next, the other layers of the second memory chips may be sequentially stacked on the bottom layer second memory chips by the thermal compression bonding process. The first bumps in every two adjacent layers of the second memory chips may be bonded to the first metal soldering pad by the thermal compression bonding process.

Specifically, as shown in FIG. 47, the remaining layers of the second memory chips 540 may be sequentially stacked on the bottom second memory chips 540 by thermal compression bonding process. The bumps 541 in every two adjacent layers of second memory chips 540 may be bonded with the first metal soldering pad 542 by the thermal compression bonding process

It should be noted that, in this embodiment, the material of the first bumps 541 may be copper tin alloy, or other materials, which are not limited in this embodiment. The material of the first metal soldering pad 542 and the second metal soldering pad 522 may be copper, or may be other materials, which are not limited in this embodiment.

It should be further noted that, in this embodiment, each first bump 541 may correspond to the first heat dissipation via 521 and the conductive via 531 of the second memory chip 540, and each second soldering pad 522 may correspond to the first heat dissipation vias 521 the conductive vias 531 of the second memory chip 540.

Further, the packaging method S500 may include S530: insulating and stacking the first memory chips on the plurality of second memory chips.

Specifically, as shown in FIG. 47, the surface of the first memory chip 530 facing the second memory chip 540 may be provided with a plurality of second bumps 532, and the surface of the first memory chip 530 facing away from the second memory chip 540 may be provided with third metal soldering pads 533.

The insulating and stacking of the first memory chips on the plurality of second memory chips may include following steps.

First, the plurality of second bumps may be bonded with the first metal soldering pads by the thermal compression bonding process.

Specifically, as shown in FIG. 47, the plurality of second bumps 532 on the first memory chip 130 may be welded to the first metal soldering pads 542 on the second memory chip 540 through a thermal compression bonding process.

It should be noted that, in this embodiment, the material of the second bump 532 may be copper tin alloy, or other materials, which are not limited in this embodiment. The material of the third soldering pad 533 may be copper metal or other materials, which is not limited in this embodiment.

Further, the packaging method S500 may also include S540: performing a thermal compression bonding on the dummy chip and the first memory chip. A plurality of second heat dissipation vias corresponding to the plurality of first heat dissipation vias may be formed on the dummy chip.

First, a plurality of second heat dissipation vias may be formed on the dummy chip, and the second heat dissipation vias may correspond to the first heat dissipation vias.

Specifically, as shown in FIG. 48, a plurality of second heat dissipation vias 511 may be formed on the dummy chip 510. The second heat dissipation vias 511 may correspond to the first heat dissipation vias 521. In this embodiment, the dummy chip 510 may be a dedicated heat dissipation chip, and the size of the second heat dissipation vias 511 may be larger than that of the first heat dissipation vias 521. In this embodiment, the cross-sectional size of the second heat dissipation vias 511 may be twice as large as the cross-sectional size of the first heat dissipation via 521.

Then, a plurality of third bumps may be formed on the surface of the dummy chip facing the first memory chip.

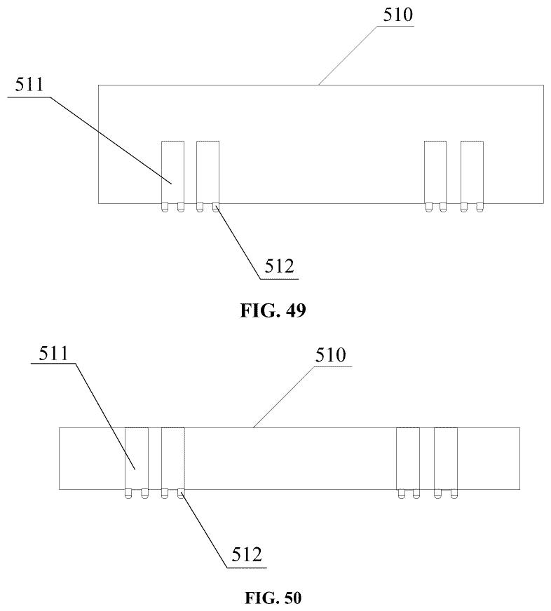

Specifically, as shown in FIG. 49, a plurality of third bumps 512 may be formed on the surface of the dummy chip 510 facing the first memory chip 530. The plurality of third bumps 512 may be in one-to-one correspondence with the third metal soldering pads 533. It should be noted that, the third bump 112 may be metal copper tin, or other materials, which are not limited in this embodiment.

It should be noted that, when the thickness of the dummy chip 510 is thin enough to expose the second heat dissipation vias 511 disposed thereon, the dummy chip 510 may not need to be thinned, but when the thickness of the dummy chip 510 is too thick to expose the second heat dissipation vias 511 disposed thereon, the dummy chip 510 may need to be thinned. In this embodiment, as shown in FIG. 50, the dummy chip 510 may need to be thinned to expose the plurality of second heat dissipation vias 511 for the heat dissipation.

It should be noted that, during the packaging process, multiple groups of second memory chips 540 may need to be disposed on the substrate 520 at the same time, and each group of second memory chips 540 may include a plurality of second memory chips 540 stacked in sequence. Thus, after the multiple groups of second memory chips 540 are stacked in sequence, they may need to be diced to form independent chip assemblies. Each chip assembly may include the substrate 520 and a plurality of second memory chips 540 stacked on the substrate 520 in sequence. The independent chips may be assembled, and then the dummy chip 510 may be bonded to the first memory chip 530.

Finally, thermal compression bonding process may be performed on the plurality of third bumps on the dummy chip and the third metal soldering pads on the first memory chip.

Specifically, the plurality of third bumps 512 on the dummy chip 510 and the third metal soldering pads 533 on the first memory chip 530 may be welded by a thermal compression bonding process.

It should be noted that, the first memory chip 530 may be only provided with the first heat dissipation vias 521 in the edge region, and the conductive vias 531 may not be provided in the central region.

By performing thermal compression bonding process on the first memory chip and the dummy chip, the package height of the high-bandwidth memory may be reduced.

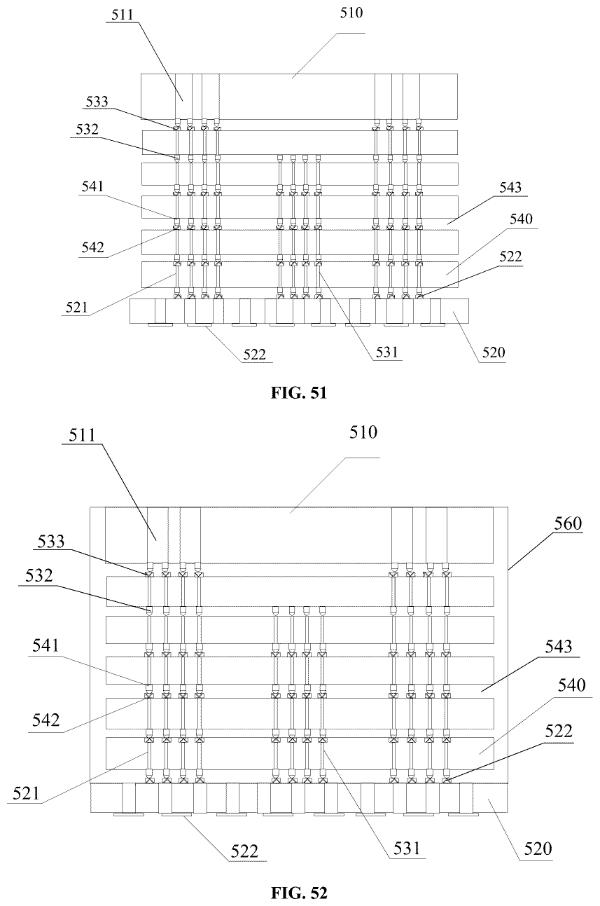

In one embodiment, as shown in FIGS. 51-53, the cross-sectional dimension of the second heat dissipation via 511 may not be smaller than the cross-sectional dimension of the first heat dissipation via 521. For example, the cross-sectional dimension of the second heat dissipation via 511 may be equal to or greater than the cross-sectional dimension of the first heat dissipation via 521. Further, in one embodiment, the cross-sectional size of the second heat dissipation via 511 may be larger than the cross-sectional size of the first heat dissipation via 521, and the cross-sectional size of the second heat dissipation via 511 may be approximately three times larger than that of the first heat dissipation vias 521. The cross-sectional size of the second heat dissipation via 511 may also be larger than that of the conductive via 531. A plurality of large-sized second heat dissipation vias 511 are provided on the dummy chip 510, they may be directly connected to an external heat sink or an active heat dissipation device to help the high-bandwidth memory to dissipate heat and improve the heat dissipation performance of the entire high-bandwidth memory.

In another embodiment, as shown in FIGS. 51-53, both the second heat dissipation vias 511 and the first heat dissipation vias 521 may be evenly distributed in the periphery of the conductive vias 531. For example, the conductive vias 531 may be located in the middle of the first memory chip 530, and the conductive vias 531 may play a signal transmission role. The second heat dissipation vias 511 and the first heat dissipation vias 521 may be evenly distributed in the periphery of the conductive vias 531 and may be mainly for the heat dissipation. It should be noted that, as shown in FIG. 51-53, the second heat dissipation vias 511, the first heat dissipation vias 521 and the conductive vias 531 may be distributed at equal intervals, and may also be distributed at unequal intervals; and no specific limitation is made.

In one embodiment, the second heat dissipation vias 511, the first heat dissipation vias 521 and the conductive vias 531 may all be TSVs. The second heat dissipation vias 511 and the first heat dissipation vias 521 may adopt the through-silicon vias process to provide the metal heat dissipation channels such that the high-bandwidth memory may have a higher heat dissipation characteristic. The second memory chip 540 and the substrate 520 may be electrically connected to achieve a better signal transmission.

Further, as shown in FIG. 46, the packaging method S500 may include S550: forming a plastic encapsulation layer. the plastic encapsulation layer may wrap the dummy chip, the substrate, the first memory chip and the plurality of second memory chips.

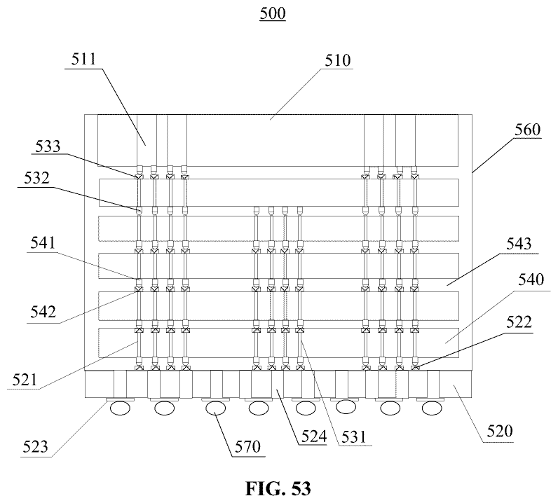

Specifically, as shown in FIG. 52, a plastic encapsulation layer 550 may be formed, and the plastic encapsulation layer 550 may wrap the dummy chip 510, the substrate 520, the first memory chip 530 and the plurality of second memory chips 540. The plastic encapsulation method may be a vacuum lamination method or a traditional plastic encapsulation process, which is not specifically limited in this embodiment. After the plastic encapsulation process is completed, a dicing process may be performed to form the final independent multi-layer stacked high-bandwidth memory packaging structure.

It should be noted that, as shown in FIG. 5-8, when the plastic encapsulation layer 550 is formed, a plastic encapsulation compound may be filled between the substrate 520 and the second memory chip 540, between the plurality of second memory chips 540, between the second memory chip 540 and the first memory chip 530 and between the first memory 530 and the dummy chip 510. The plastic encapsulation compound filled between the chips may play an insulating role. The wrapping of the plastic encapsulation compound may play a protection role to the first bumps 541, the second bumps 532 and the third bumps 512. When the encapsulation compound is filled in the chips, the cost may be saved.

In one embodiment, as shown in FIG. 53, the surface of the substrate 520 facing away from the second memory chip 540 may be provided with a plurality of fourth metal soldering pads 523. A plurality of metal soldering balls 560 may be formed on the fourth metal soldering pads 523, and may be connected to outside through the plurality of soldering balls 560. The substrate 520 may be further provided with a plurality of substrate conductive vias 524, and the size of the substrate conductive vias 524 may be larger than that of the conductive vias 531.

In the multi-layer stacked high-bandwidth memory packaging method and packaging structure of the present disclosure, the packaging method firstly may insulate and stacks a plurality of second memory chips on a substrate, and then, the first memory chips may be insulated and stacked on the plurality second memory chips. The first memory chip and the plurality of second memory chips may be provided with a plurality of first heat dissipation vias. Finally, the dummy chip and the first memory chip may be bonded by a thermal compression process. Using a dummy chip may ensure the sufficient mechanical protection for the first memory chip and the plurality of second memory chips. At the same time, a plurality of second heat dissipation vias corresponding to the first heat dissipation vias may be formed on the dummy chip, which may provide heat dissipation channels for the high-bandwidth memory, and the plurality of second heat dissipation vias may be directly connected with external heat sinks or active heat dissipation devices. Thus, the heat dissipation performance of the entire high-bandwidth memory may be improved, and the performance of the broadband memory may be improved.

FIG. 53 illustrates another exemplary packaging structure a multi-layer stacked memory according to various disclosed embodiments. As shown in FIG. 53, the packaging structure 500 may include a dummy chip 510, a substrate 520, a first memory chip 530, a plastic encapsulation layer 550, and a plurality of second memory chips 540.

The plurality of second memory chips 540 may be stacked on the substrate 520. The first memory chip 530 may be disposed on a side of the plurality of second memory chips 540 facing away from the substrate 520. The dummy chip 510 may be disposed on the side of the first memory chip 530 facing away from the substrate 520, and the dummy chip 510 may be bonded to the first memory chip 530 by a thermal compression bonding process.

The plastic encapsulation layer 550 may wrap the dummy chip 510, the substrate 520, the first memory chip 530 and the plurality of second memory chips 540. The first memory chip 530 and the plurality of second memory chips 540 may each be provided with a plurality of first heat dissipation vias 521, and the dummy chip 510 may be provided with a plurality of second heat dissipation vias 511 corresponding to the plurality of first heat dissipation vias 521. The plurality of second memory chips 540 may be provided with a plurality of conductive vias 531. The plurality of first heat dissipation vias 121 may be connected to the plurality of second heat dissipation vias 511, which may improve the heat dissipation of the first memory chip 530 and the plurality of second memory chips 540.

In one embodiment, the cross-sectional dimension of the second heat dissipation via 511 may not be smaller than the cross-sectional dimension of the first heat dissipation via 521. That is, the cross-sectional dimension of the second heat dissipation via 511 may be equal to or greater than the cross-sectional dimension of the first heat dissipation via 521. In one embodiment, the cross-sectional size of the second heat dissipation vias 511 is larger than the cross-sectional size of the first heat dissipation through hole 521, and the cross-sectional size of the second heat dissipation via 511 may be approximately three times larger than that of the first heat dissipation via 521; and the cross-sectional size of the second heat dissipation via 511 may be also larger than that of the conductive via 531. When a large-sized second heat dissipation via 511 is provided on the dummy chip 510, it may be directly connected with an external heat sink or an active heat dissipation device to the high-bandwidth memory to dissipate heat, and the heat dissipation performance of the entire high-bandwidth memory may be improved.

In one embodiment, as shown in FIG. 53, both the second heat dissipation vias 511 and the first heat dissipation vias 521 may be distributed on the periphery of the conductive vias 531. For example, the conductive vias 531 may be located in the middle of the chip, and the conductive vias 531 may play a signal transmission role. The second heat dissipation vias 511 and the first heat dissipation vias 521 may be uniformly distributed on in the periphery of the conductive vias 531 and may play the heat dissipation role. It should be noted that, as shown in the figure, the second heat dissipation vias 511, the first heat dissipation vias 521 and the conductive vias 531 may be distributed at equal intervals, or may be distributed at unequal intervals, which are not specifically limited in this embodiment.

In one embodiment, the second heat dissipation via 511, the first heat dissipation via 521 and the conductive via 531 may all be TSVs. The second heat dissipation vias 511 and the first heat dissipation vias 521 may adopt through-silicon vias to provide the metal heat dissipation channels such that the high-bandwidth memory may have higher heat dissipation characteristics. The second memory chip 540 and the substrate 520 may be electrically connected to achieve a better signal transmission.

In one embodiment, as shown in the FIG. 53, the second memory chips 540 may be connected by a first thermal compression bonding structure, the second memory chips 540 may be connected with the substrate 520 by a second thermal compression bonding structure, the first memory chips 530 and the second memory chips 540 may be connected by a third thermal compression bonding structure, and the dummy chip 510 and the first memory chip 530 may be connected by a fourth thermal compression bonding structure.

Specifically, the first thermal compression bonding structure may include a plurality of first bumps 541 disposed on the surface of the second memory chip 540 facing the substrate 520 and a plurality of first metal soldering pads 542 disposed on the surface of the second memory chip 540 facing away from the substrate 520. The first bump 541 may be connected to the first soldering pad 542 by thermal compression bonding process.

The second thermal compression bonding structure may include a second soldering pad 522 disposed on the surface of the substrate 520 facing the second memory chip 540 and a first bump 541 disposed on the second memory chip 540. The second metal soldering pad 522 may be connected to the first bumps 141 by the thermal compression bonding.

The third thermal compression bonding structure may include a plurality of second bumps 532 on the surface of the first memory chip 530 facing the second memory chip 540, and the first metal soldering pads 542 disposed on the second memory chip 540. The plurality of second bumps 532 may be connected to the first metal soldering pads 542 by the thermal compression bonding process.

The fourth thermal compression bonding structure may include a plurality of third bumps 512 disposed on the surface of the dummy chip 510 facing the first memory chip 530, and a third metal soldering pad 533 disposed on the first memory chip 530. The plurality of third bumps 512 may be connected to the third metal soldering pads 533 by the thermal compression bonding process.

It should be noted that, in this embodiment, the materials of the first bumps 541, the second bumps 532 and the third bumps 512 may be copper-tin alloy for example, copper-tin bumps, or may be other materials, which is not specifically limited in this embodiment. Materials of the first metal soldering pads 542, the second metal soldering pad 522 and the third metal soldering pad 533 may be metal copper, which is not specifically limited in this embodiment.

In one embodiment, the packaging structure may further include a plurality of soldering balls 560 disposed on the surface of the substrate 520 facing away from the second memory chip 540, and the packaging structure 500 may be connected to outside through the plurality of soldering balls 560. The surface of the substrate 520 facing away from the second memory chip 540 may be provided with a plurality of fourth soldering pads 523, and a plurality of soldering balls 560 may be provided on the fourth soldering pads 523. The substrate 520 may be further provided with a plurality of substrate conductive vias 524, and the size of the substrate conductive vias 524 may be larger than that of the conductive vias 531.

In one embodiment, a plastic encapsulation material may be filled between the substrate 520 and the second memory chip 540, between the plurality of second memory chips 540, between the second memory chip 540 and the first memory chip 530, and between the first memory chip 530 and the dummy chip 510. The plastic encapsulation compound filled between the chips may play an insulating role. The wrapping of the plastic encapsulation compound may play a protection role for the first bumps 541, the second bumps 532 and the third bumps 512. Filling the plastic encapsulant between the chips may save the cost.

In the packaging structure of the present disclosure, by arranging a dummy chip on the first memory chip, and setting a plurality of first heat dissipation vias on the dummy chip, the high-bandwidth memory may be provided with a mechanical protection and the heat dissipation performance may be improved.

It can be understood that the above embodiments are only exemplary embodiments adopted to illustrate the principle of the present disclosure, but the present disclosure is not limited thereto. For those skilled in the art, without departing from the spirit and essence of the present disclosure, various modifications and improvements can be made, and these modifications and improvements are also regarded as the protection scope of the present disclosure.

What is claimed is:

1. A packaging method of multi-layer stacked memory, comprising:
providing a buffer chip, a plurality of dummy chips and a plurality of first memory chips, wherein a dummy chip of the plurality of dummy chips is provided with a groove body, the buffer chip is provided with a plurality of first conductive vias, and the plurality of first memory chips are provided with a plurality of second conductive vias corresponding to the plurality of first conductive vias;
respectively fixing each of the plurality of first memory chips in the groove body of the dummy chip to form a plurality of micro-memory modules; and
sequentially hybrid-bonding and stacking the plurality of the micro-memory modules on the buffer chip, wherein an orthographic projection of a micro-memory module of the plurality of micro-memory modules on the buffer chip coincides with the buffer chip.

2. The method according to claim 1, wherein respectively fixing each of the plurality of first memory chips in the groove body of the dummy chip to form a plurality of micro-memory modules comprises:
sequentially performing a hybrid-bonding process on the plurality of first memory chips, and stacking the plurality of first memory chips to form a first stacked memory module; and
fixing the first stacked memory module in the groove body of the dummy chip to form the plurality micro-memory module.

3. The method according to claim 1, wherein the plurality of dummy chip includes a plurality first dummy chips, second dummy chips and third dummy chips and the first dummy chip is further provided with a plurality of cooling vias, further comprising:
anodic bonding the second dummy chip and the third dummy chip, forming a second groove body at a position of the first groove body corresponding the second dummy chip and the third dummy chip, and forming a second cooling via at a position of the third dummy chip corresponding to the first cooling via, wherein the second cooling via is connected to the first cooling via;
fixing the first memory chip in the second groove body to form a second micro-memory module; and
sequentially hybrid-bonding the second micro-memory module on the buffer chip, wherein an orthographic projection of the second micro-memory module on the buffer chip coincides with the buffer chip.

4. The method according to claim 1, wherein a first passivation layer and a first metal soldering pad are disposed on a first surface of a first memory chip of the plurality of first memory chips, and a second passivation layer and a second metal soldering pad are provided on a second surface of the first memory chip, wherein each of plurality of first memory chips is respectively fixed in the groove body of the dummy chip to form the plurality of micro-memory modules comprises:
forming a first adhesive layer between a bottom wall of the groove body and the first surface of the first memory chip to fix the first memory chip in the groove body;
forming a second adhesive layer on the dummy chip and the second surface of the first memory chip, and filling a portion of the second adhesive in a gap between a sidewall of the groove body and the first memory chip;
removing the second adhesive layer on the second surface of the first memory chip to expose the second passivation layer and the second metal soldering pad; and
removing the first adhesive layer on the first surface of the first memory chip to expose the first passivation layer and the first metal soldering pad to form the plurality of micro-memory modules.

5. The method according to claim 4, wherein removing the second adhesive layer on the second surface of the first memory chip to expose the second passivation layer and the second metal soldering pad comprises:
polishing and chemically cleaning the dummy chip and the second surface of the first memory chip to completely remove the second adhesive layer on the second surface of the first memory chip while retaining a portion the second adhesive layer on the surface of the dummy chip.

6. The method according to claim 4, wherein a third passivation layer and a third metal soldering pad are disposed on a side of the buffer chip facing the memory micro-module, wherein sequentially hybrid-bonding and stacking the plurality of micro-memory modules on the buffer chip comprises:
bonding the second passivation layer of a first layer micro-memory module with the third passivation layer on the buffer chip,
bonding the second metal soldering pad of the first layer micro-memory modules and the third metal soldering pad on the buffer chip; and
sequentially hybrid-bonding and stacking each remaining layer of micro-memory module on the first layer micro-memory module, wherein the first passivation layer and the second passivation layer in every two adjacent layers of micro-memory modules are bonded, and the first metal soldering pad and the second metal soldering pad in every two adjacent layers of micro-memory modules are bonded.

7. The method according to claim 1, after sequentially hybrid-bonding and stacking the plurality of micro-memory modules on the buffer chip, further comprising:
forming a plurality of bumps on a surface of the buffer chip facing away from the micro-memory module, wherein the plurality of bumps correspond to the plurality of first conductive vias.

8. The packaging method according to claim 4, wherein performing the hybrid-bonding process on the plurality of first memory chips in sequence to form the first stacked memory module comprises:
bonding the first passivation layer and the second passivation layer in every two adjacent layers of first memory chips; and
bonding the first metal soldering pads and the second metal soldering pads in every two adjacent layers of first memory chips.

9. The packaging method according to claim 2, wherein fixing the first stacked memory module in the groove body of the dummy chip to form the micro-memory module comprises:
forming a first adhesive layer on a first surface of a top layer first memory chip in the first stacked memory module to fix the first stacked memory module in the groove body;
forming a second adhesive layer on the dummy chip and a second surface of a bottom layer first memory chip in the first stacked memory module, and filling a portion of the second adhesive in a gap between a sidewall of the groove body and the first stacked memory module;
removing the second adhesive layer on the second surface of the bottom layer first memory chip to expose the second passivation layer and the second metal soldering pad; and
removing the first adhesive layer on the first surface of the top layer first memory chip to form the memory micro-module.

10. The packaging method according to claim 3, before anodic bonding the second dummy chip and the third dummy chip, further comprising:
forming a cooling through groove in the second dummy chip, wherein the cooling through groove is connected to the second cooling via.

11. The packaging method according to claim 4, further comprising:
filling the portion of the second adhesive into the first cooling via; and
removing the first adhesive layer on the first surface of the first memory chip to expose the first cooling via to form the first micro-memory module.

12. A packaging method of a multi-layer stacked structure, comprising:
providing a dummy chip, a buffer chip, a first memory chip and a plurality of second memory chips, the plurality of second memory chips and the buffer chip are further provided with a plurality of conductive vias;
sequentially insulating and stacking the plurality of second memory chips on the buffer chip;
bonding the first memory chip and the dummy chip;
insulating and stacking the bonded first memory chips on the plurality of second memory chips; and
forming a plastic encapsulation layer to wrap the dummy chip, the buffer chip, the first memory chip and the plurality of second memory chips,
wherein:
the dummy chip is provided with a plurality of first heat dissipation vias, the buffer chip, the first memory chip and the plurality of second memory chips are provided with a plurality of second heat dissipation vias corresponding to the plurality of first heat dissipation vias, or the first memory chip and the plurality of second memory chips are all provided with a plurality of first heat dissipation vias.

13. The packaging method according to claim 12, wherein the buffer chip is a substrate, wherein sequentially insulating and stacking the plurality of second memory chips on the buffer chip comprises:
sequentially insulating and stacking the plurality of second memory chips on the substrate.

14. The packaging method according to claim 12, wherein:
a cross-sectional size of the first heat dissipation via is not smaller than a cross-sectional size of the second heat dissipation via; and
the first heat dissipation via and the second heat dissipation via are both disposed in a peripheral region of the plurality of conductive vias.

15. A packaging structure of a multi-layer stacked memory, comprising:
a buffer chip; and
a plurality of micro-memory modules,
wherein:
the buffer chip is provided with a plurality of first conductive vias; and
the plurality of micro-memory modules are sequentially stacked on the buffer chip, and an orthographic projection of the micro-memory modules on the buffer chip coincides with the buffer chip.

16. The packaging structure according to claim 15, wherein:
each of the micro-memory modules includes a dummy chip and a first memory chip;
the dummy chip is provided with a groove body;
the groove body is provided with a first memory chip; and
the first memory chip is provided with a plurality of second conductive vias corresponding to and electrically connected to the plurality of first conductive vias.

17. The packaging structure according to claim 15, wherein:
each of the plurality of micro-memory modules includes a dummy chip and a stacked memory module;
the dummy chip is provided with a groove body;
the groove body is provided with the stacked memory module;
the stacked memory module includes a plurality of first memory chips stacked in sequence;
first memory chips in every two adjacent layers are hybrid-bonded; and
the first memory chips are provided with a plurality of second conductive vias corresponding to and electrically connected to the plurality of first conductive vias.

18. The packaging structure according to claim 15, further comprising:
a second micro-memory module,
wherein:
the buffer chip is provided with a plurality of first conductive vias;
the second micro-memory module is hybrid-bonded and stacked on the buffer chip, the plurality of first micro-memory modules are hybrid-bonded and stacked on the second micro-memory module and an orthographic projection of the first micro-memory modules and the second micro-memory module on the buffer chip coincides with the buffer chip;
each of the plurality of first micro-memory modules includes a first memory chip and a dummy chip provided with a first groove body and a plurality of first cooling vias;
the first groove body is provided with a first memory chip;
the first memory chip is provided with a plurality of second conductive vias corresponding to and electrically connected to the plurality of first conducive vias;
the second micro-memory module includes a first memory chip, a second dummy chip, and a third dummy chip sandwiched between the first dummy chip and the second dummy chip;
the second dummy chip and the third dummy chip are provided with a second groove body corresponding to the first groove body;
the second groove body is provided with the first memory chip; and
the third dummy chip is provided with a second cooling via corresponding to and connected to the first cooling via.

19. The packaging structure according to claim 15, further comprising:
a dummy chip;
a first memory chip;
a plastic encapsulation layer; and
a plurality of second memory chips,
wherein:
the plurality of second memory chips are stacked on the buffer chip;
the first memory chip is disposed on a side of the plurality of second memory chips facing away from the buffer chip;
the dummy chip is bonded and connected to a side of the first memory chip facing away from the buffer chip through a bonding structure;
the plastic encapsulation layer wraps the dummy chip, the buffer chip, the first memory chip and the plurality of second memory chips; and,
the dummy chip is provided with a plurality of first heat dissipation vias, and the buffer chip, the first memory chip and the plurality of second memory chips are all provided with a plurality of second heat dissipation vias corresponding to the plurality of first heat dissipation vias, and the plurality of second memory chips and the buffer chip are further provided with a plurality of conductive vias.

20. The packaging structure according to claim 19, wherein:
the buffer chip includes a substrate
wherein:
the plurality of second memory chips are sequentially stacked on the substrate;
the first memory chip is disposed on a side of the plurality of second memory chips facing away from the substrate;
the dummy chip is disposed on a side of the first memory chip facing away from the substrate and thermal compression bonded with the first memory chip;
the plastic encapsulation layer wraps the dummy chip, the substrate, the first memory chip and the plurality of second memory chips; and,
the first memory chip and the plurality of second memory chips are all provided with a plurality of first heat dissipation vias, the dummy chip is provided with a plurality of second heat dissipation vias corresponding to the plurality of first heat dissipation vias, and the plurality of second memory chips are provided with a plurality of conductive vias.
